(19) United States
(12) Patent Application Publication
(10) Pub. No.: US 2012/0079691 A1
(43) Pub. Date: Apr. 5, 2012

(54) METHOD OF MANUFACTURING PACKAGES, PIEZOELECTRIC VIBRATORS OSCILLATOR, ELECTRONIC APPARATUS, AND RADIO CLOCK

(76) Inventor: Kenji Takano, Chiba-shi (JP)

(21) Appl. No.: 13/240,487

(22) Filed: Sep. 22, 2011

(30) Foreign Application Priority Data
Oct. 5, 2010 (JP) 2010-225945

(51) Int. Cl. H01L 41/22

(52) U.S. Cl. 29/25.35

(57) ABSTRACT

The present invention provides a novel method of producing piezoelectric vibrators in which a plurality of substrates are formed at once from a wafer, and the wafer is formed with a plurality of electrode holes formed in the respective substrates. Using holders each having a plurality of electrode columns held thereon, the plurality of electrode columns are substantially simultaneously inserted in the electrode holes formed in the wafer.

### RELATED APPLICATIONS

This application claims priority under 35 U.S.C. §119 to Japanese Patent Application No. 2010-225945 filed on Oct. 5, 2010, the entire content of which is hereby incorporated by reference.

### BACKGROUND OF THE INVENTION

1. Technical Field

The present invention relates to a method of manufacturing packages, a piezoelectric vibrator, an oscillator, an electronic apparatus, and a radio clock.

2. Description of the Related Art

For example, a piezoelectric vibrator using crystal or the like as a time instance source, a timing source of control signals or the like, a reference signal source, and so on is used in mobile phone sets or portable digital assistant terminal. Various types of such piezoelectric vibrators are known, and a piezoelectric vibrator of surface mount device type having a two-layer structure is known as one of these piezoelectric vibrators.

The piezoelectric vibrator of this type has a two-layer structure having a first substrate and a second substrate packaged by being bonded directly to each other, and an electronic components is accommodated in the cavity formed between the both substrates. As one of the piezoelectric vibrators having the two-layer structure, a quartz vibrator including external connection electrodes on one surface of a base member (which corresponds to the “first substrate” in this application), quartz connection electrodes on the other surface of the base member, a quartz vibrator mounted on the quartz connection electrodes, and through electrodes formed of metallic members (which corresponds to a “core member” in this application) and penetrating through the base member, wherein the external connection electrodes and the quartz connection electrodes are electrically connected is known (for example, see JP-A-2002-124845).

Incidentally, in JP-A-2002-124845, there is a description saying that the through electrodes are formed by using pin-type metallic members. As a detailed method of forming the through electrodes, a method of forming small-diameter through holes on the base member, heating the base member, and driving the pin-type metallic members while the base members are still in a hot and softened state is described.

However, the method of forming the through electrodes described in JP-A-2002-124845, it is necessary to drive the pin-type metallic members individually into all the through holes while the substrate is still in the hot and softened state. Therefore, there is a problem in that a large number of steps are required.

In addition, since the pin-type metallic members are inserted individually, there is a risk of manufacturing defects such as missing of insertion of the pin-type metallic members or occurrence of positional displacement of the pin-type metallic members due to the erroneous insertion. Accordingly, establishment of continuity of the through electrodes may be failed.

### SUMMARY OF THE INVENTION

Accordingly, it is an object of the invention to provide a method of manufacturing packages having through electrodes which may be formed easily and has high degree of reliability, a piezoelectric vibrator manufactured by the method of manufacturing packages described above, an oscillator, an electronic apparatus, and a radio clock.

In order to achieve the above-described object, there is provided a method of manufacturing packages in which an electric component may be sealed in a cavity formed between a mutually bonded plurality of substrates, including: a through electrode forming step for forming a plurality of through electrodes which penetrate through a first substrate from among a plurality of the substrates in the thickness direction and configured to bring an inside of the cavity and an outside of the package into continuity, wherein the through electrode forming step includes: a conducting member forming step for forming a conducting member having a plurality of core members which become all the through electrodes included in a single piece of the package and a connecting portion connecting a plurality of the core members; a depression forming step for forming a plurality of depressions on the first substrate; a core member inserting step for inserting a plurality of the core members of the conducting member into the depressions respectively; a sealing step for sealing gaps between inner surfaces of the depressions and outer surfaces of the core members; and a polishing step for polishing a first surface side and a second surface side of the first substrate to remove the connecting portion and causing the core members to be exposed from the first surface side and the second surface side.

According to the invention, the conducting member includes a plurality of core members which become all the through electrodes included in a single piece of the package and the respective core members are connected by the connecting portion. Therefore, in the core member inserting step, a plurality of the core members may be inserted into all the depressions included in a single piece of the package at once. Therefore, since the core members may be arranged easily in all the depressions included in a single piece of the package of the first substrate, the through electrodes may be formed easily.

Also, since the respective core members are connected by the connecting portion, missing of insertion of the core members is avoided by simultaneous insertion of the respective core members into all the depressions included in a single piece of the package at once. In addition, when the respective core members are inserted, positional displacement between the core members arranged in a single piece of the package is avoided. Therefore, manufacturing defects are prevented and hence the continuity of the through electrodes is established, so that so that the through electrodes with high reliability may be formed.

Preferably, in the through electrode forming step, the through electrodes included in a plurality of the packages are formed on a first substrate wafer for forming a plurality of the first substrates, and in the core member inserting step, the conducting members are arranged in the respective first substrate forming areas on the first substrate wafer and a plurality of the core members on the conducting members are inserted into the depressions respectively.

For example, it is conceivable to insert a plurality of core members included in a plurality of the packages into the respective depressions at once using the conducting members in which a plurality of the core members which become all the through electrodes included in a plurality of the packages. However, in the case of the conducting members in which a plurality of the core members which become all the through electrodes included in a plurality of the packages, the respective core members are significantly apart from each other. Therefore, if the conducting member is subject to thermal expansion due to the temperature change or the like during manufacturing, the positional displacement of the respective core members due to thermal expansion may be accumulated, and hence the positional displacement of the respective core members tends to increase. Therefore, the error in position where the through electrodes are formed may occur and hence the reliable continuity of the through electrodes may not be secured.

In contrast, in the core member inserting step in the invention, the respective core members are inserted into the respective depressions for each first substrate by using the conducting member in which a plurality of the core members which become all the through electrodes included in a single piece of the package are connected. Accordingly, accumulation of the positional displacement due to thermal expansion of the respective core members does not occur among a plurality of the first substrates. Therefore, manufacturing defects are prevented and hence the continuity of the through electrodes is established, so that so that the through electrodes with high reliability may be formed.

Preferably, in the sealing step, the first substrate is adhered to the outer surfaces of the core members by pressing the surface of the first substrate using a pressurizing mold and heating the first substrate to a temperature higher than a softening point of the first substrate.

According to the invention, a plurality of the core members which become all the through electrodes included in a single piece of the package is connected by the connecting portion. Therefore, even when the first substrate is adhered to the outer surfaces of the core members, positional displacement does not occur between the respective core members arranged in a single piece of the package. Therefore, manufacturing defects are prevented and hence the continuity of the through electrodes is established, so that the through electrodes with high reliability may be formed. In addition, since the first substrate is adhered to the outer surfaces of the core members, the through electrodes with high hermeticity may be formed.

Preferably, the depressions are through holes, in the core member inserting step, the core members are inserted into the through holes from openings of the through hole on one of the first surface side and the second surface side, and the sealing step includes: a glass frit filling step for filling gaps between inner surfaces of the through holes and outer surfaces of the core members with glass frit from the openings of the through holes on the other one of the first surface side and the second surface side; and a sintering step for sintering and hardening the glass frit filled in the gaps.

According to the invention, a plurality of the core members which become all the through electrodes included in a single piece of the package is connected by the connecting portion. Therefore, even when the through holes are filled with the glass frit, positional displacement does not occur between the respective core members arranged in a single piece of the package. Therefore, manufacturing defects are prevented and hence the continuity of the through electrodes is established, so that the through electrodes with high reliability may be formed. In addition, since the glass frit filled in the gaps between the inner surfaces of the through holes and the outer surfaces of the core members is sintered and hardened, the through electrodes with high hermeticity may be formed.

Preferably, the conducting member is formed by forging.

Preferably, the conducting member is formed by forming the core members by half-blanking a block member from the one surface side toward the other surface side of the block member and forming the connecting portion from the block member other than the core members.

Preferably, the conducting member is formed by stamping the core members and the connecting portion from a flat-plate member and bending the core members so as to extend along the direction of a normal line of the connecting portion.

According to the invention, the conducting member may be formed with high degree of accuracy at low cost. In particular, when the conducting member is formed by being stamped from the flat-plate member, a number of conducting members may be formed at once, so that the conducting member may be formed at lower cost.

A piezoelectric vibrator in the invention includes a piezoelectric vibration reed encapsulated in the interior of the package manufactured by the method of manufacturing packages described above.

According to the invention, since the piezoelectric vibration reed is encapsulated in the interior of the package having the through electrodes which may be formed easily and have high degree of reliability, the piezoelectric vibrator with high degree of reliability may be provided at low cost.

Preferably, an oscillator according to the invention includes a piezoelectric vibration reed and an integrated circuit encapsulated in the interior of the package manufactured by the method of manufacturing packages described above.

The oscillator having the integrated circuit encapsulated therein according to the invention includes a large number of through electrodes, and hence the effect of the invention that the core members may be arranged easily is specifically effective. According to the oscillator in the invention, since the piezoelectric vibration reed and the integrated circuit is encapsulated in the interior of the package having the through electrodes which may be formed easily and have high degree of reliability, the oscillator with high degree of reliability may be provided at low cost.

In the oscillator according to the invention includes the piezoelectric vibrator described above is electrically connected to the integrated circuit as an oscillation element.

Also, in an electronic apparatus according to the invention, the piezoelectric vibrator described above is electrically connected to a clocking unit.

In a radio clock according to the invention, the piezoelectric vibrator described above is electrically connected to a filter unit.

According to the oscillator, the electronic apparatus, and the radio clock, since the piezoelectric vibrator having the through electrodes which may be formed easily and have high degree of reliability is provided, the oscillator, the electronic apparatus, and the radio clock superior in reliability may be provided at low cost.

According to the invention, the conducting member includes a plurality of core members which become all the through electrodes included in a single piece of the package and the respective core members are connected by the connecting portion. Therefore, in the core member inserting step, a plurality of the core members may be inserted to all the depressions included in a single piece of the package at once. Therefore, since the core members may be arranged easily in all the depressions included in a single piece of the package of the first substrate, the through electrodes may be formed easily.

Also, since the respective core members are connected by the connecting portion, missing of insertion of the core members is avoided by inserting the respective core members into all the depressions included in a single piece of the package at once. In addition, when the respective core members are inserted, positional displacement between the core members arranged in a single piece of the package does not occur. Therefore, manufacturing defects are prevented and hence the continuity of the through electrodes is established, so that the through electrodes with high reliability may be formed.

### BRIEF DESCRIPTION OF THE DRAWINGS

FIG. 1 is an appearance perspective view of a piezoelectric vibrator according to a first embodiment;

FIG. 2 is a drawing showing an internal configuration of the piezoelectric vibrator shown in FIG. 1 and is a plan view showing a state in which the lid substrate is removed;

FIG. 3 is a cross-sectional view taken along the line A-A in FIG. 2;

FIG. 4 is an exploded perspective view of the piezoelectric vibrator shown in FIG. 1;

FIG. 5 is a flowchart showing a method of manufacturing piezoelectric vibrators according to the first embodiment;

FIG. 6 is an exploded perspective view of a wafer member;

FIG. 7 is a perspective view of a conducting member according to the first embodiment;

FIG. 8A is an explanatory drawing of a conducting member forming step and is a cross-sectional side view showing a state before the conducting member is formed;

FIG. 8B is an explanatory drawing of the conducting member forming step and is a cross-sectional side view showing a state after the conducting member is formed;

FIG. 9A is an explanatory drawing of a depression forming step and is a perspective view of a base substrate wafer;

FIG. 9B is an explanatory drawing of the depression forming step and is a cross-sectional view taken along the line B-B in FIG. 9A;

FIG. 10 is an explanatory drawing of a core member inserting step;

FIG. 11A is an explanatory drawing of a sealing step showing a state before sealing;

FIG. 11B is an explanatory drawing of the sealing step showing a state after sealing;

FIG. 12 is an explanatory drawing of a polishing step;

FIG. 13A is an explanatory drawing showing a state before the conducting member is formed according to a first modification of the first embodiment;

FIG. 13B is an explanatory drawing showing a state after the conducting member is formed according to the first modification of the first embodiment;

FIG. 14A is an explanatory drawing showing stamping according to a second modification of the first embodiment;

FIG. 14B is an explanatory drawing showing a raising of the core members according to the second modification of the first embodiment;

FIG. 15 is a flowchart showing a method of manufacturing piezoelectric vibrators according to a second embodiment;

FIG. 16 is an explanatory drawing of a through hole forming step;

FIG. 17 is an explanatory drawing of a core member inserting step;

FIG. 18 is an explanatory drawing showing a grass frit filing step in the sealing step;

FIG. 19 is an explanatory drawing of the polishing step;

FIG. 20 is a perspective view of a conducting member according to a third embodiment;

FIG. 21A is an explanatory cross-sectional side view of an oscillator using a conducting member according to the third embodiment;

FIG. 21B is an explanatory plan view of the oscillator using the conducting member according to the third embodiment;

FIG. 22 is a configuration drawing showing an embodiment of the oscillator;

FIG. 23 is a configuration drawing showing an embodiment of an electronic apparatus; and

FIG. 24 is a configuration drawing showing an embodiment of a radio clock.

### DETAILED DESCRIPTION OF THE PREFERRED EMBODIMENTS

### First Embodiment, Piezoelectric Vibrator

Referring now to the drawings, a piezoelectric vibrator according to a first embodiment of the invention will be described.

In the description given below, a first substrate wafer will be described as a base substrate wafer. Also in the description given below, the bonding surface of a base substrate of the package (piezoelectric vibrator) with respect to a lid substrate will be described as a first surface U and an outside surface of the base substrate will be described as a second surface L.

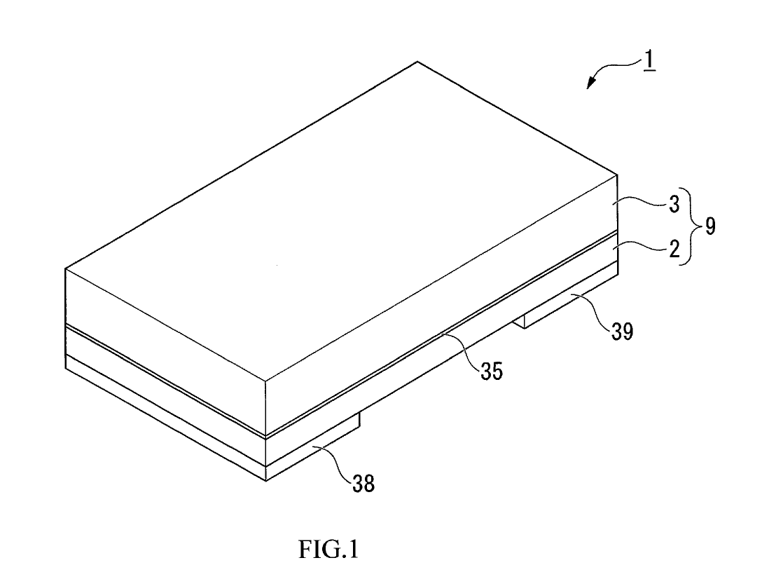

FIG. 1 is an appearance perspective view of a piezoelectric vibrator 1.

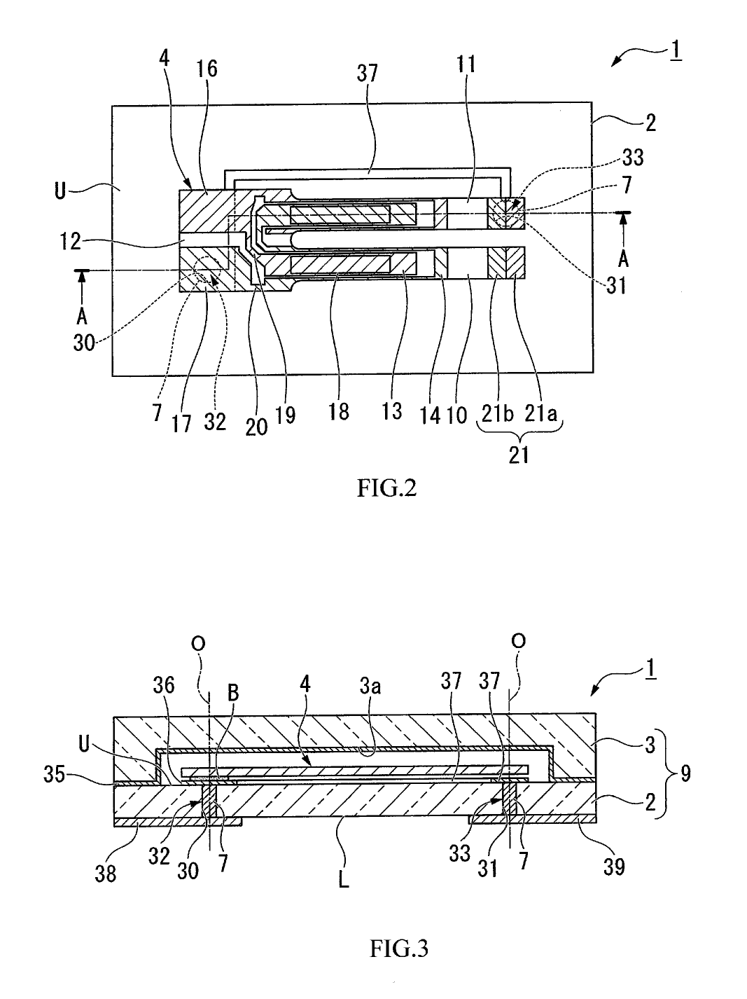

FIG. 2 is a drawing showing an internal configuration of the piezoelectric vibrator 1 and is a plan view showing a state in which the lid substrate 3 is removed.

FIG. 3 is a cross-sectional view taken along the line A-A in FIG. 2.

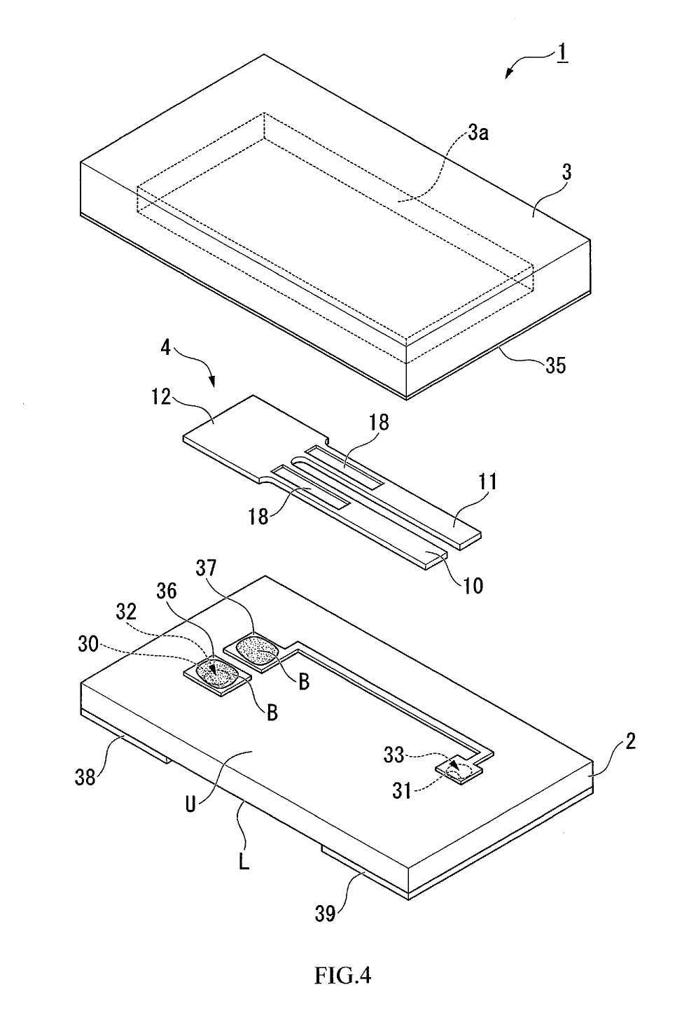

FIG. 4 is an exploded perspective view of the piezoelectric vibrator 1 shown in FIG. 1.

In FIG. 4, for the sake of easy understanding of the drawing, illustration of excitation electrodes 13 and 14, draw-out electrodes 19, 20, mount electrodes 16 and 17, and a weight metal film 21, described later, is omitted.

As shown in FIG. 1 to FIG. 4, a piezoelectric vibrator 1 according to the first embodiment is the surface mount device-type piezoelectric vibrator 1 including a package 9 having a base substrate 2 and a lid substrate 3 bonded by anodic wafer bonding via a bonding film 35, and a piezoelectric vibration reed 4 accommodated in a cavity 3a of the package 9.

### Piezoelectric Vibration Reed

The piezoelectric vibration reed 4 is a vibration reed having a tuning fork shape formed of a piezoelectric material such as crystal, lithium tantalite, or lithium niobate and is configured to vibrate when a predetermined voltage is applied thereto. The piezoelectric vibration reed 4 includes a pair of vibrating arm portions 10, 11 arranged in parallel to each other, a base member 12 integrally fixing proximal end sides of a pair of the vibrating arm portions 10, 11, and groove portions 18 formed on both main surfaces of a pair of the vibrating arm portions 10, 11. The groove portions 18 are formed from the proximal end sides of the vibrating arm portions 10, 11 along the longitudinal direction of the vibrating arm portions 10, 11 to substantially midsections thereof.

Excitation electrodes 13, 14 and draw-out electrodes 19, 20 are each formed with a single layer film of chrome (Cr), which is the same material as a base layer of mount electrodes 16, 17, described later. Accordingly, film formation of the excitation electrodes 13, 14 and the draw-out electrodes 19, 20 is achieved simultaneously with the film formation of the base layers of the mount electrodes 16, 17.

The excitation electrodes 13, 14 are electrode which causes a pair of the vibrating arm portions 10, 11 to vibrate in the direction toward or away from each other at a predetermined resonance frequency. The first excitation electrode 13 and the second excitation electrode 14 are formed on the outer surfaces of a pair of the vibrating arm portions 10, 11 by patterning in a state of being electrically disconnected, respectively.

The mount electrodes 16, 17 each are a laminated film including Cr and gold (Au), and are formed by forming a Cr film having a good adhesion with respect to quartz as a base layer and then forming a thin film of Au on the surface thereof as a finishing layer.

The distal ends of a pair of the vibrating arm portions 10, 11 are each coated with a weight metal film 21 for tuning (frequency tuning) the vibrating state of themselves to vibrate within a range of a predetermined frequency. The weight metal film 21 is divided into a coarse-tuning film 21a used when tuning the frequency coarsely and a fine-tuning film 21b used when tuning the same finely. By performing the frequency tuning using the coarse-tuning film 21a and the fine-tuning film 21b, the frequencies of a pair of the vibrating arm portions 10, 11 may be tuned to fall within a range of the nominal frequency of the device.

### Package

As shown in FIGS. 1 to 4, the base substrate 2 and the lid substrate 3 are each an anodically bondable substrate formed of a glass material, for example, soda lime glass, and is formed into a substantially plate shape. On a bonding surface of the lid substrate 3 with respect to the base substrate 2 is formed with a cavity 3a configured to accommodate the piezoelectric vibration reed 4.

Formed on the entirety of the bonding surface of the lid substrate 3 with respect to the base substrate 2 is a joint film 35 (bonding material) for the anodic wafer bonding. In other words, the joint film 35 is formed on a frame area around the cavity 3a in addition to the entire inner surface of the cavity 3a. The joint film 35 in the first embodiment is formed of aluminum (Al), the joint film 35 may be formed of silicon (Si) or Cr. The joint film 35 and the base substrate 2 are bonded by anodic wafer bonding and the cavity 3a is vacuum-sealed.

As shown in FIG. 3, the piezoelectric vibrator 1 includes through electrodes 32, 33 which penetrate through the base substrate 2 in the thickness direction, and bring the inside of the cavity 3a and the outside of the piezoelectric vibrator 1 into continuity. The through electrodes 32, 33 are arranged so as to extend along center axes 0 of the through holes 30, 31 and are each formed of a core member 7 which electrically connects the piezoelectric vibrator 4 and the outside. The base substrate 2 melted in a manufacturing process is firmly secured to the outer peripheral surfaces of the core members 7. Accordingly, the through electrodes 32, 33 maintain hermeticity in the cavities.

The core members 7, which become the through electrodes 32, 33 are formed of a metallic material such as silver (Ag), Al, Ni alloy, Kovar, and the like. The core members 7 are inserted into the base substrate 2 as the through electrodes 32, 33, it is preferable to form the core member 7 of a metal having a linear coefficient of expansion close to that of the glass material of the base substrate 2, for example, alloy (42 alloy) containing 58 weight percent of iron (Fe) and 42 weight percent of Ni.

The core members 7 are each formed into a substantially column shape and are formed so as to be aligned with the positions where the through electrodes 32, 33 are formed. The core members 7 are not limited to have the substantially column shape and, may be formed into a prism shape, for example.

A pair of drawing electrodes 36, 37 are patterned on a first surface U side of the base substrate 2. Also, the bumps B having a tapered shape and formed of Au or the like are formed respectively on a pair of the drawing electrodes 36, 37, and a pair of the mount electrodes for the piezoelectric vibration reed 4 are mounted using the bumps B. Accordingly, the one mount electrodes 16 of the piezoelectric vibration reed 4 is brought into continuity with the one through electrode 32 via the one drawing electrode 36, and the other mount electrode 17 is brought into continuity with the other through electrode 33 via the other drawing electrode 37.

A pair of external electrodes 38, 39 are formed on a second surface L of the base substrate 2. A pair of the external electrodes 38, 39 are formed at both end portions of the base substrate 2 in the longitudinal direction and are electrically connected respectively to a pair of the through electrodes 32, 33.

When activating the piezoelectric vibrator 1 configured in this manner, a predetermined drive voltage is applied to the external electrodes 38, 39 formed on the base substrate 2. Accordingly, a voltage is applied to the first excitation electrode 13 and the second excitation electrode 14 of the piezoelectric vibration reed 4, so that a pair of the vibrating arm portions 10, 11 may be vibrated at a predetermined frequency in the direction toward and away from each other. Then, the vibration of a pair of the vibrating arm portions 10, 11 may be used as a time instance source, a timing source of the control signal, a reference signal source, and so on.

### Method of Manufacturing Piezoelectric Vibrator

Subsequently, a method of manufacturing a piezoelectric vibrator 1 described above will be described with reference with a flowchart.

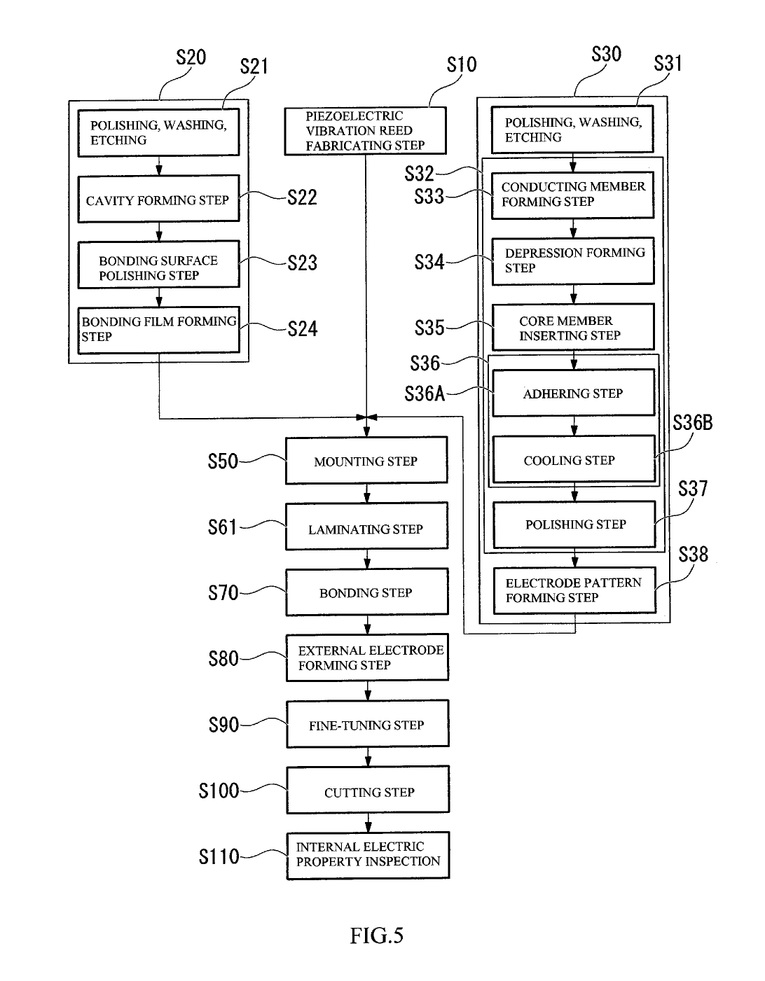

FIG. 5 is a flowchart showing a method of manufacturing the piezoelectric vibrators 1 according to the first embodiment.

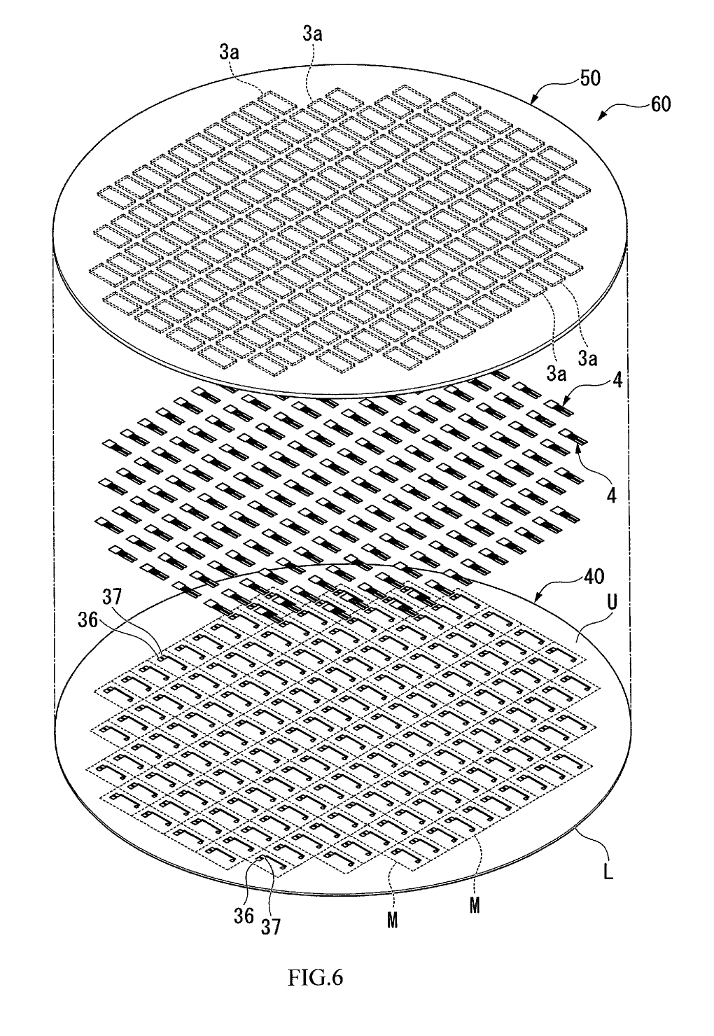

FIG. 6 is an exploded perspective view of a wafer member 60. Broken lines shown in FIG. 6 are cutting lines M to be cut in a cutting step performed later.

The method of manufacturing the piezoelectric vibrators 1 according to the first embodiment mainly includes a piezoelectric vibration reed fabricating step S10, a lid substrate wafer fabricating step S20, a base substrate wafer fabricating step S30, and an assembling step (from S50 onward). From among the respective steps, the piezoelectric vibration reed fabricating step S10, the lid substrate wafer fabricating step S20, and the base substrate wafer fabricating step S30 may be performed in parallel.

### Piezoelectric Vibration Reed Fabricating Step S10

In the piezoelectric vibration reed fabricating step S10, the piezoelectric vibration reed 4 is fabricated. More specifically, Lambert row stone of quartz is sliced at a predetermined angle and mirror polishing process such as polishing is performed thereon, so that a wafer of a predetermined thickness is obtained. Subsequently, patterning into an outer shape of the piezoelectric vibrating strip 4 is performed by lithography technique and patterning of the metallic film is performed thereon, so that the exciting electrodes 13, 14, the draw-out electrodes 19, 20, the mount electrodes 16, 17, and the weight metal film 21 are formed. Subsequently, a coarse tuning of the resonance frequency of the piezoelectric vibration reed 4 is performed. With the procedure described above, the piezoelectric vibration reed fabricating step S10 is ended.

### Lid Substrate Wafer Fabricating Step S20

In the lid substrate wafer fabricating step S20, a lid substrate wafer 50, which becomes a lid substrate later, is fabricated. First of all, after having performed polishing and washing on the disc-shaped lid substrate wafer 50 formed of the soda lime glass to a predetermined thickness, an affected layer on the topmost surface thereof is removed by etching or the like (S21). Subsequently, in the cavity forming step S22, a plurality of cavities 3a are formed on a bonding surface of the lid substrate wafer 50 with respect to a base substrate wafer 40. Formation of the cavities 3a is performed by hot press molding or etching. Subsequently, in a bonding surface polishing step S23, the bonding surface with respect to the base substrate wafer 40 is polished.

Subsequently, in the bonding film forming step S24, a bonding film 35 formed of Al (see FIG. 3) is formed on the bonding surface with respect to the base substrate wafer 40 described later. The bonding film 35 may be formed on the entirety of the inner surface of the cavity 3a in addition to the bonding surface with respect to the base substrate wafer 40. Accordingly, patterning of the bonding film 35 is not necessary, and hence reduction of the manufacturing cost is achieved. Formation of the bonding film 35 may be achieved by a film forming method such as spattering, CVD, or the like. Since the bonding surface polishing step S23 is performed before the bonding film forming step S24, the flatness of the surface of the bonding film 35 is ensured, so that stable bonding with respect to the base substrate wafer 40 is achieved.

### Base Substrate Wafer Fabricating Step S30

In the base substrate wafer fabricating step S30, the base substrate wafer 40, which becomes a base substrate later, is fabricated. First of all, after having performed polishing and washing on the disc-shaped base substrate wafer 40 formed of the soda lime glass to a predetermined thickness, an affected layer on the topmost surface thereof is removed by etching or the like (S31).

### Through Electrode Forming Step S32

Subsequently, a through electrode forming step S32 for forming a pair of through electrodes 32, 33 on the base substrate wafer 40 is performed.

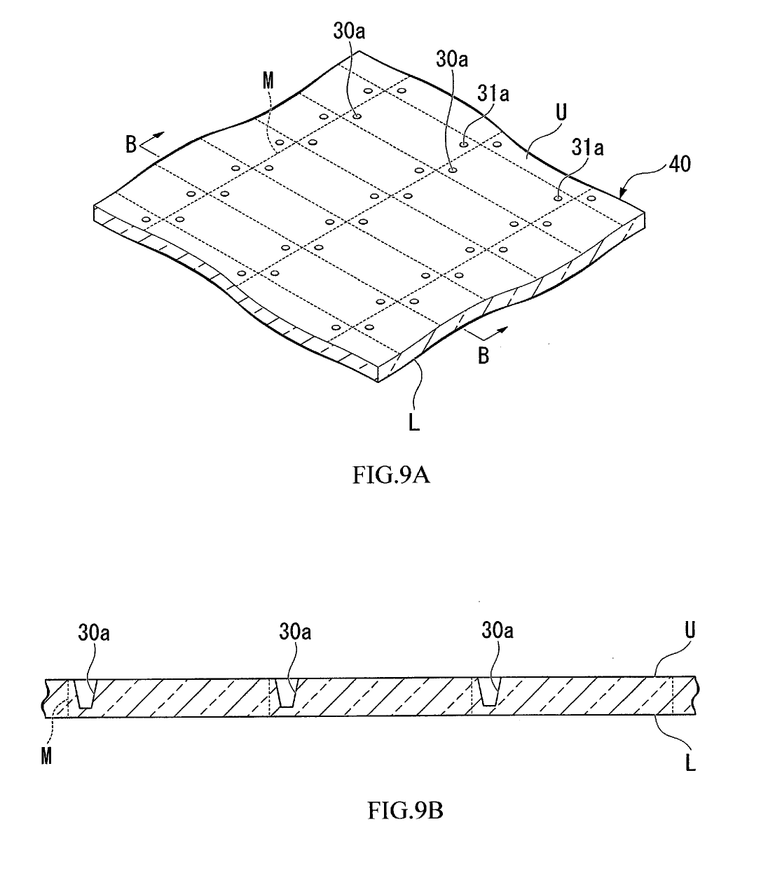

The through electrode forming step S32 includes a conducting member forming step S33 for forming a conducting member 5 having the core members 7 and a connecting portion 6, a depression forming step S34 for forming depressions 30a, 31a (see FIG. 9) on the first surface U of the base substrate wafer 40, a core member inserting step S35 for inserting the core members 7 into the depressions 30a and 31a, a sealing step for sealing gaps between the inner surfaces of the depressions 30a, 31a and the outer surfaces of the core members 7, and a polishing step S37 for polishing the base substrate wafer 40 to expose the core members 7. The conducting member forming step S33 may need only be finished before the core member inserting step S35 and may be performed independently from the through electrode forming step S32.

### Conducting Member Forming Step S33

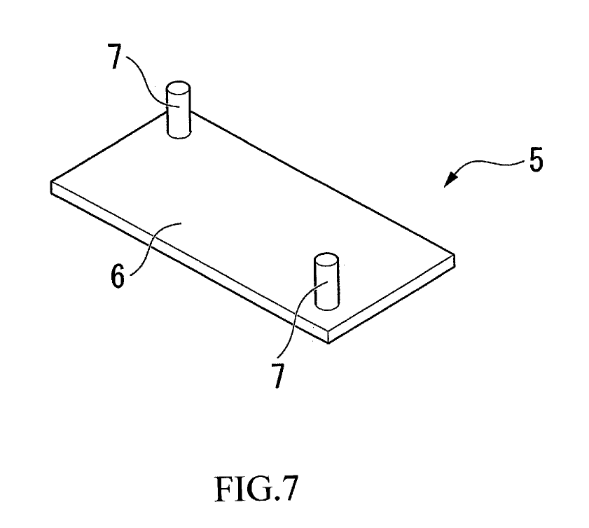

FIG. 7 is a perspective view of a conducting member 5 according to the first embodiment.

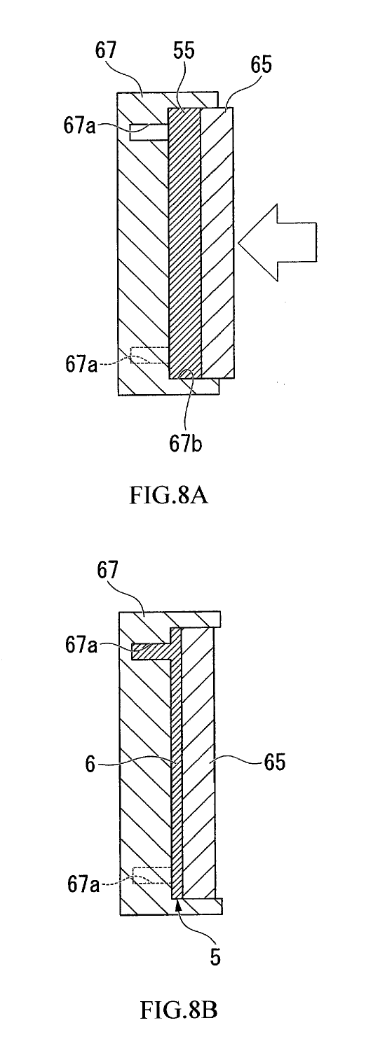

FIG. 8A is an explanatory drawing of a conducting member forming step S33 and is a cross-sectional side view showing a state before the conducting member is formed, and FIG. 8B is an explanatory drawing of the conducting member forming step and is a cross-sectional side view showing a state after the conducting member is formed.

Subsequently, the conducting member forming step S33 for forming the conducting member 5 shown in FIG. 7 is performed. In the conducting member forming step S33 in the first embodiment, the conducting member 5 is formed by forging. The conducting member forming step S33 may be either cold forging or hot forging.

The conducting member 5 in the first embodiment includes a pair of the core members 7 which become the through electrodes 32, 33, and the connecting portion 6 configured to couple a pair of the core members 7. The conducting member 5 is formed of a metallic material such as silver (Ag), Al, Ni alloy, Kovar, and the like in the same manner as the core members 7 described above.

In the through electrode forming step S32 in the first embodiment, the bottomed depressions 30a, 31a (see FIGS. 9A and 9B) are formed on the base substrate wafer 40 in the depression forming step S34, described later, and the core members 7 are inserted into the depressions 30a, 31a. Therefore, the core members 7 are formed to have a length shorter than the thickness of the base substrate 2, which is a length causing no interference with the bottom portions of the depressions 30a, 31a when inserted into the depressions 30a, 31a (for example, on the order of approximately 500 μm). The diameter of the core members 7 is set as appropriate according to the magnitude of a current passing through the through electrodes 32, 33.

One end sides of the core members 7 are connected by the connecting portion 6. The connecting portion 6 is a flat-panel member having, for example, a substantially rectangular shape in plan view. The outline of the connecting portion 6 is formed slightly smaller than the outline of the package 9 (for example, 3.2 mm×1.5 mm). The connecting portion 6 is not limited to have the substantially rectangular shape, and may need only connect one end sides of all the core members 7.

The conducting member 5 described above is formed as follows.

As shown in FIG. 8A, a molding device used in the conducting member forming step S33 is made up of a cavity mold 67 and a core mold 65. The cavity mold 67 is formed with a receiving portion 67b having an opening formed into a size slightly larger than the outline of the conducting member 5 so as to be capable of receiving a base material 55 as a material of the conducting member 5 and hole portions 67a for forming the core members 7. The core mold 65 is a flat panel metal mold and is connected to a press machine, not shown, configured to press the core mold 65 toward the cavity mold 67.

A detailed procedure of the conducting member forming step S33 will be described. First of all, the base material 55 is set in the receiving portion 67b. Subsequently, the core mold 65 is moved toward the cavity mold 67, to press the base material 55 set in the receiving portion 67b of the cavity mold 67. Accordingly, as shown in FIG. 8B, the base material 55 is deformed and part of the base material 55 enters the hole portions 67a of the cavity mold 67, so that the core members 7 are formed. At the same time, the connecting portion 6 is formed by the base material 55 remaining in the receiving portion 67b of the cavity mold 67. With the procedure described thus far, the conducting member 5 shown in FIG. 7 is formed.

### Depression Forming Step S34

FIG. 9A is an explanatory drawing of a conducting member forming step S34 and is a perspective view of a base substrate wafer 40, and FIG. 9B is an explanatory drawing of a conducting member forming step and is a cross-sectional view taken along the line B-B in FIG. 9A. Dot lines shown in FIGS. 8A and 8B are cutting lines M.

Subsequently, a depression forming step S34 for forming the depressions 30a, 31a for allowing insertion of the core members 7 on the first surface U of the base substrate wafer 40 is performed. The depressions 30a, 31a may be formed on the second surface L of the base substrate wafer 40.

In the first embodiment, a pair of the through electrodes 32, 33 are formed on a single piece of the base substrate 2 as shown in FIG. 2. Therefore, as shown in FIG. 9A, a pair of the depressions 30a, 31a corresponding to a pair of the through electrodes 32, 33 are formed in an area corresponding to a single piece of the base substrate 2 surrounded by the cutting lines M of the base substrate wafer 40.

The depressions 30a, 31a are formed by heat pressing, sand-blasting, etching, or the like. In the first embodiment, the depressions 30a, 31a are formed so that the inner diameter increases gradually from the second surface L side to the first surface U side of the base substrate wafer 40 as shown in FIG. 9B.

### Core Member Inserting Step S35

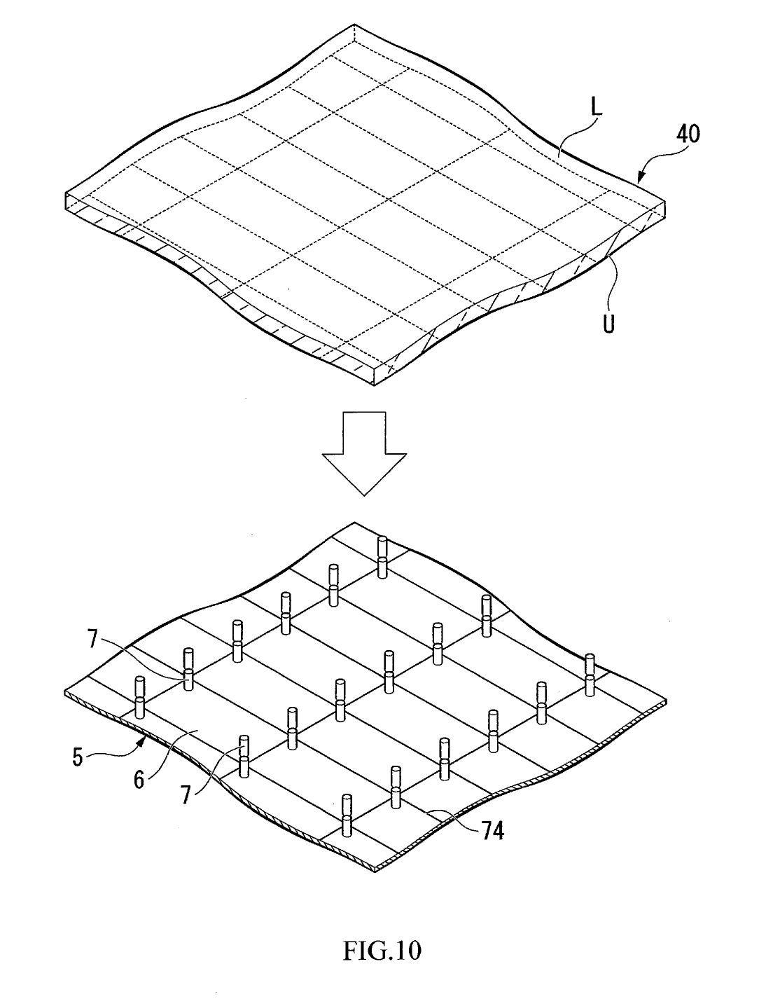

FIG. 10 is an explanatory drawing of the core member inserting step S35.

Subsequently, the bonding film 35 for arranging the core members 7 of the conducting member 5 in the depressions 30a, 31a is performed.

A detailed procedure of the core member inserting step S35 will be described. First of all, the conducting members 5 are set on the arranging jig 74.

The arranging jig 74 is, for example, a flat-panel-shaped member, and is configured to allow the conducting members 5 to be arranged next to each other. The conducting members 5 are set on the arranging jig 74 with the connecting portions 6 being in abutment with the arranging jig 74 and the core members 7 directed upward.

Subsequently, the first surface U of the base substrate wafer 40, which is the side where the depressions 30a, 31a are opened, is faced toward the arranging jig 74, and the arranging jig 74 are laminated while aligning in position. Accordingly, the core members 7 may be arranged in the depressions 30a, 31a. The next sealing step S36 is performed in a state in which the arranging jig 74 and the base substrate wafer 40 are laminated.

### Sealing Step S36

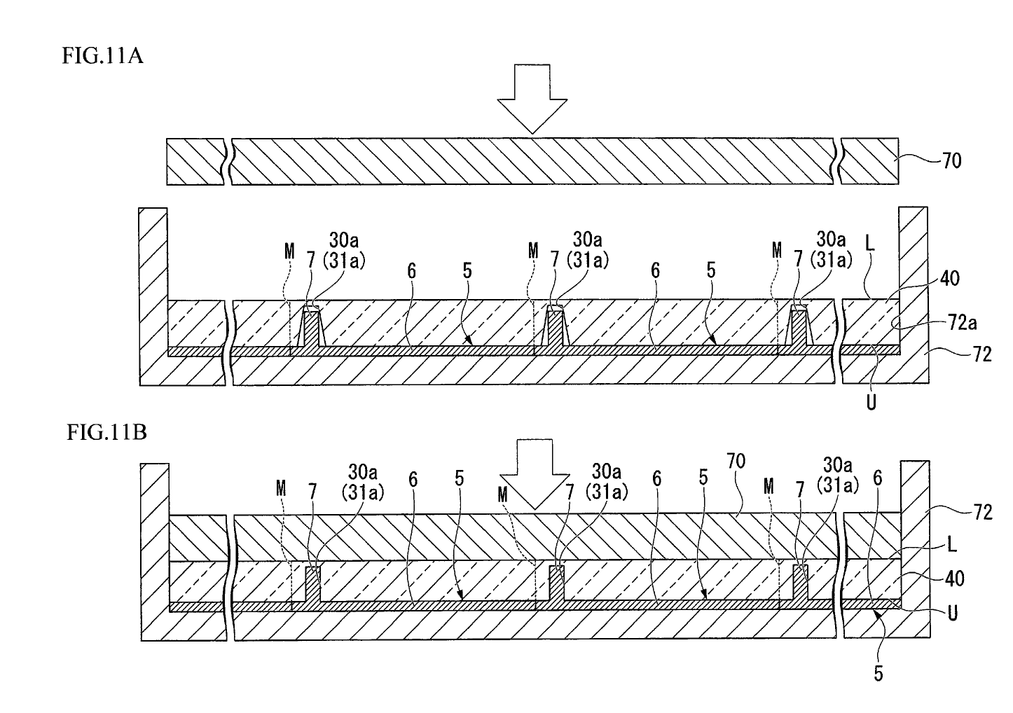

FIG. 11A is an explanatory drawing of a sealing step S36 showing a state before sealing and FIG. 11B is an explanatory drawing of the sealing step S36 showing a state after sealing.

Subsequently, the sealing step S36 for sealing the gaps between the inner surfaces of the depressions 30a, 31a and the outer surfaces of the core members 7 is performed. The sealing step S36 includes an adhering step S36A for adhering the base substrate wafer 40 to the core members 7 and a cooling step S36B for cooling the base substrate wafer 40 after adhesion.

### Adhering Step S36A

The adhering step S36A is performed by using a receiving mold 72 having a receiving mold depression 72a configured to hold the base substrate wafer 40 and a pressurizing mold 70 configured to press the base substrate wafer 40 arranged in the receiving mold depression 72a as shown in FIGS. 11A and 11B. The receiving mold depression 72a of the receiving mold 72 has an opening formed to have a size slightly larger than the outline of the base substrate wafer 40. The pressurizing mold 70 is a flat-panel-shaped mold configured to press the base substrate wafer 40 and is formed to have an outline slightly smaller than the shape of the opening of the receiving mold depression 72a. Formed at an end of the pressurizing mold 70 is a slit, not shown, which penetrates through the pressurizing mold 70, so as to serve as a release hole for air and excessive glass material of the base substrate wafer 40 when the base substrate wafer 40 is heated and pressed.

Firstly, in the adhering step S36A, the base substrate wafer 40 is set in the receiving mold 72. More specifically, the conducting member 5 and the base substrate wafer 40 are set in the receiving mold depression 72a in a state of being placed one on top of another in this sequence from the bottom portion of the receiving mold depression 72a toward the opening side.

Subsequently, the conducting members 5 and the base substrate wafer 40 set in the receiving mold 72 are placed in a heating furnace, not shown, and heated therein. Then, the base substrate wafer 40 is pressed by the pressurizing mold 70 at a pressure of, for example, 30 to 50 g/cm² using a press machine or the like arranged in the heating furnace. The heating temperature is higher than a softening point (for example 545° C.) of a glass of the base substrate wafer 40, which is, for example, about 900° C.

In this manner, the base substrate wafer 40 is deformed by pressing the base substrate wafer 40 while heating, so that the gaps between the inner surface of the depressions 30a, 31a and the outer surfaces of the core members 7 may be filled.

Preferably, the heating temperature is increased gradually and is stopped increasing at a timing of, for example, 550° C., which is higher than the softening point of glass by approximately 5° C., and is held at the same temperature, and is increased again to approximately 900° C. By stopping the increase of the temperature once at a temperature approximately 5° C. higher than the softening point of the glass and keeping the same temperature, softening of the base substrate wafer 40 may be uniformized.

### Cooling Step S36B

Subsequently, the cooling step S36B for cooling the base substrate wafer 40 is performed.

Cooling of the base substrate wafer 40 is performed by lowering the temperature gradually from approximately 900° C., which is a temperature at the time of heating in the adhering step S36A. At this time, the receiving mold 72 in which the base substrate wafer 40 is set is taken out from the interior of the heating furnace and then is cooled. The base substrate wafer 40 is secured to the outer surfaces of the core members 7 by being cooled and hardened, whereby the gaps between the inner surfaces of the depressions 30a, 31a and the outer surfaces of the core members 7 may be sealed.

The cooling speed is preferably set so that the cooling speed from a strain point of glass as a material of the base substrate wafer 40 +50° C. which is to a strain point −50° C. becomes slower than the cooling speed from approximately 900° C. to the strain point +50° C. Cooling from the strain point +50° C. to the strain point −50° C. is performed by moving the base substrate wafer 40 to the furnace. Accordingly, the base substrate wafer 40 is prevented from being strained.

### Polishing Step S37

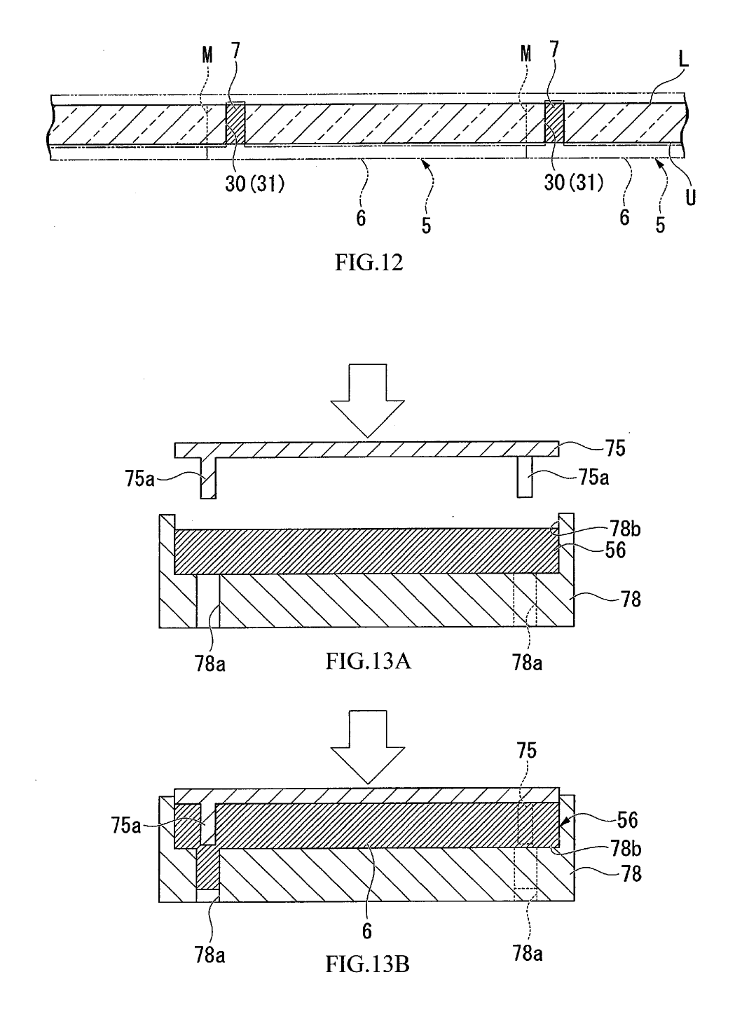

FIG. 12 is an explanatory drawing of the polishing step S37.

Subsequently, the base substrate wafer 40 is taken out from the receiving mold 72 and the polishing step S37 for polishing the first surface U side and the second surface L side of the base substrate wafer 40 is performed. By polishing the first surface U side of the base substrate wafer 40, the connecting portions 6 of the conducting members 5 are removed, and the core members 7 are exposed from the first surface U. Also, by polishing the second surface L side of the base substrate wafer 40, the bottom portions (see FIGS. 11A and 11B) of the depressions 30a, 31a are removed and the core members 7 are exposed from the second surface L. By the polishing step S37, the end portions of the core members 7 may be reliably exposed from the first surface U and the second surface L.

At the time point when the polishing step S37 is performed, the through electrode forming step S32 is ended.

Subsequently, a drawing electrode forming step S40 for forming a plurality of drawing electrodes 36, 37 which are electrically connected to the through electrodes 32, 33 respectively on the first surface U is performed (see FIG. 6). Then, the tapered-shaped bumps B (see FIG. 3) formed respectively of gold or the like are formed on the drawing electrodes 36, 37. In FIG. 6, illustration of the bumps is omitted for the sake of easy understanding of the drawing. At this time point, the base substrate wafer fabricating step S30 is ended.

Piezoelectric Vibrator Assembling Step from Mounting Step S50 Onward

Subsequently, the mounting step S50 for bonding the piezoelectric vibration reed 4 to the drawing electrodes 36, 37 of the base substrate wafer 40 via the bumps B is performed. More specifically, the base members 12 of the piezoelectric vibration reed 4 are placed on the bumps B, and then, ultrasonic vibration is applied to the piezoelectric vibration reed 4 in a state of pressing the piezoelectric vibration reed 4 against the bumps B while heating the bumps B to a predetermined temperature. Accordingly, as shown in FIG. 3, the base member 12 is mechanically secured to the bumps B in a state in which the vibrating arm portions 10, 11 of the piezoelectric vibration reed 4 are floated from the first surface U of the base substrate wafer 40. Also, the mount electrodes 16 and 17 and the drawing electrodes 36, 37 are electrically connected.

After having mounted the piezoelectric vibration reeds 4, a laminating step S60 for laminating the lid substrate wafer 50 on the base substrate wafer 40 is performed as shown in FIG. 6. Specifically, the both wafers 40 and 50 are aligned at a proper position with reference to a reference mark or the like, not shown. Accordingly, the piezoelectric vibration reeds 4 mounted on the base substrate wafer 40 is accommodated in the cavities 3a.

After having the laminating step S60, the both laminated wafers 40 and 50 are put in an anodic wafer bonding apparatus, not shown, and a bonding step S70 for applying a predetermined voltage in predetermined temperature atmosphere to anodically bond the wafers 40 and 50 is performed. When a predetermined voltage is applied between the bonding film 35 and the base substrate wafer 40, an electrochemical reaction occurs in an interface between the bonding film 35 and the base substrate wafer 40, and the both are tightly adhered to each other and anodically bonded. Accordingly, the piezoelectric vibration reeds 4 may be sealed in the cavities 3a, and the bonded wafer member 60 including the base substrate wafer 40 and the lid substrate wafer 50 may be obtained. FIG. 6 shows a state in which the wafer member 60 is disassembled for the sake of easy understanding of the drawing.

Subsequently, an external electrode forming step S80 for forming a plurality of pairs of the external electrodes 38, 39 (see FIG. 3) electrically connected to the pairs of the through electrodes 32, 33 respectively by patterning of a conductive material on the second surface L of the base substrate wafer 40 is performed. With this step, the piezoelectric vibration reeds 4 are brought into continuity with the external electrodes 38, 39 via the through electrodes 32, 33.

Subsequently, in the state of the wafer member 60, a fine-tuning step S90 for fine-tuning the frequencies of the individual piezoelectric vibrators 1 sealed in the cavities 3a so as to be kept within a predetermined range is performed. Specifically, a predetermined voltage is applied from the external electrodes 38, 39 continuously to measure the frequencies while vibrating the piezoelectric vibration reeds 4. In this state, a laser beam is applied from the outside of the base substrate wafer 40 to cause the fine-tuning film 21b of the weight metal film 21 shown in FIG. 2 to evaporate. Accordingly, the frequencies of the piezoelectric vibrators 1 may be fine-tuned so as to fall within a range of the nominal frequency.

After having ended the fine-tuning of the frequencies, a cutting step S100 for cutting the bonded wafer member 60 along the cutting lines M is performed. More specifically, in a first step, an UV tape is adhered to the surface of the base substrate wafer 40 of the wafer member 60. Subsequently, a laser is applied from the side of the lid substrate wafer 50 along the cutting lines M (scribing). Then, a cutting blade is pressed against the cutting lines M from the surface of the UV tape to break the wafer member 60 into pieces (braking). Subsequently, a UV ray is applied to separate the UV tape. Accordingly, the wafer member 60 may be separated to a plurality of piezoelectric vibrators 1. The wafer member 60 may be cut using other methods such as dicing.

A step sequence such that the fine-tuning step S90 is performed after having performed the cutting step S100 and cut into individual pieces of piezoelectric vibrators 1 is also applicable. However, by performing the fine-tuning step S90 precedently, the fine-tuning in a state of the wafer member 60 is achieved, so that a plurality of the piezoelectric vibrators 1 may be fine-tuned efficiently. Accordingly, improvement of the throughput is preferably achieved.

Subsequently, an internal electric property inspection S110 in the interior is performed. In other words, a resonance frequency, a resonant resistance value, and a drive level characteristics (dependency of the resonance frequency and the resonant resistance value on an excitation power) of the piezoelectric vibration reeds 4 are measured and checked. The insulative resistance characteristics are also checked. Then, finally, an appearance inspection of the piezoelectric vibrators is performed for final check of dimensions, quality, and the like. Accordingly, manufacture of the piezoelectric vibrators 1 is ended.

### Effects of First Embodiment

According to the first embodiment, the conducting member 5 includes a plurality of core members 7 which becomes all the through electrodes 32, 33 included in a single piece of the piezoelectric vibrator 1 and the respective core members 7 are connected by the connecting portion 6. Therefore, in the core member inserting step S35, a plurality of the core members 7 may be inserted to all the depressions 30a, 31a included in a single piece of the piezoelectric vibrator 1 at once. Therefore, since the core members 7 may be arranged easily in the all the depressions 30a, 31a included in the single piece of the piezoelectric vibrator 1 of the base substrate wafer 40, the through electrodes 32, 33 may be formed easily. Also, since the respective core members 7 are connected by the connecting portion 6, missing of insertion of the core members 7 is avoided by inserting the respective core members 7 into all the depressions 30a, 31a included in a single piece of the piezoelectric vibrator 1 at once. In addition, when the respective core members 7 are inserted, positional displacement between the core members 7 arranged in a single piece of the piezoelectric vibrator 1 is avoided. Therefore, manufacturing defects are prevented and hence the continuity of the through electrodes 32, 33 is secured, the through electrodes 32, 33 with high reliability may be formed.

In the core member inserting step S35 in this embodiment, the core members 7 are inserted respectively into the depressions 30a, 31a for each base substrate forming area using the conducting member 5 in which the respective core members 7 to be arranged on a single piece of the piezoelectric vibrator 1 are connected. Therefore, accumulation of the positional error of the respective core members 7 in a plurality of the base substrate forming area does not occur. Therefore, manufacturing defects are prevented and hence the continuity of the through electrodes 32, 33 is ensured, the through electrodes 32, 33 with high reliability may be formed.

### First Modification of First Embodiment, Another Conducting Member Forming Step

Subsequently, a first modification of the first embodiment will be described.

FIG. 13A is an explanatory drawing of showing a state before the conducting member is formed according to a first modification of the first embodiment, and FIG. 13B is an explanatory drawing showing a state after the conducting member is formed according to a first modification of the first embodiment. In the conducting member forming step S33 in the first embodiment, the conducting member 5 is formed by forging. However, the first modification of the first embodiment is different from the first embodiment in that the conducting member 5 is formed by half blanking. Steps other than the conducting member forming step S33 are the same as those in the above-described embodiment, and hence repeated description is omitted.

As shown in FIGS. 13A and 13B, in the conducting member forming step S33 in the first modification, an upper mold 75 and a lower mold 78 are used to form the conducting member 5 from a block member 56.

The block member 56 is a member having a thickness on the order of 500 μm to 700 μm formed of a metallic material such as Ag, Al, Ni alloy, Kovar or the like. The outline of the block member 56 is formed slightly smaller than the outline of the package 9 (for example, 3.2 mm×1.5 mm).

The upper mold 75 is formed with upright column-shaped punches 75a corresponding to the positions where the core members 7 are formed. In the half blanking, it is necessary for the punches 75a to stop immediately before blanking the block member 56 completely. Therefore, the length of the punches 75a is formed to be slightly shorter than the thickness of the block member 56. The diameter of the punches 75a is formed to be substantially the same as or slightly smaller than the diameter of the core members 7.

The lower mold 78 is formed with a lower mold depression 78b which may hold the block member 56. The lower mold depression 78b has an opening formed to be slightly larger than the outline of the block member 56. The lower mold depression 78b is formed on the bottom portion thereof with dices 78a penetrating through the lower mold 78 at positions corresponding to the positions where the punches 75a are formed. Parts of the block member 56 half blanked by the punches 75a enter the dices 78a to form the core members 7.

A detailed procedure of the conducting member forming step S33 in the first modification will be described. First of all, the block member 56 is set in the lower mold depression 78b. Subsequently, the upper mold 75 is moved toward the lower mold 78 to press the block member 56 set in the lower mold depression 78b of the lower mold 78 using the punches 75a of the upper mold 75 by a pressing machine or the like, not shown. At this time, the upper mold 75 is moved slowly toward the lower mold 78 so as not to stamp the block member 56 with the punches 75a completely. Accordingly, as shown in FIG. 13B, parts of the block member 56 corresponding to the punches 75a of the block member 56 is subject to plastic deformation, and is brought into so-called a half-blanked state, so that the core members 7 are formed. Simultaneously, the block member 56 remaining in the lower mold depression 78b serves as the connecting portion 6. With the procedure described thus far, the conducting member 5 having the core members 7 and the connecting portion 6 is formed.

### Second Modification of First Embodiment, Another Conducting Member Forming Step

Subsequently, a second modification of the first embodiment will be described.

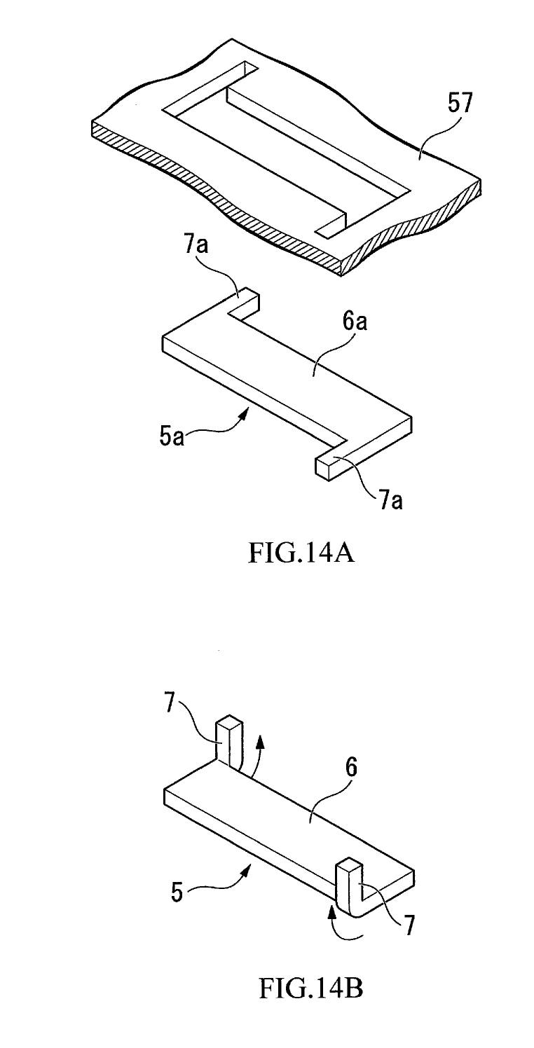

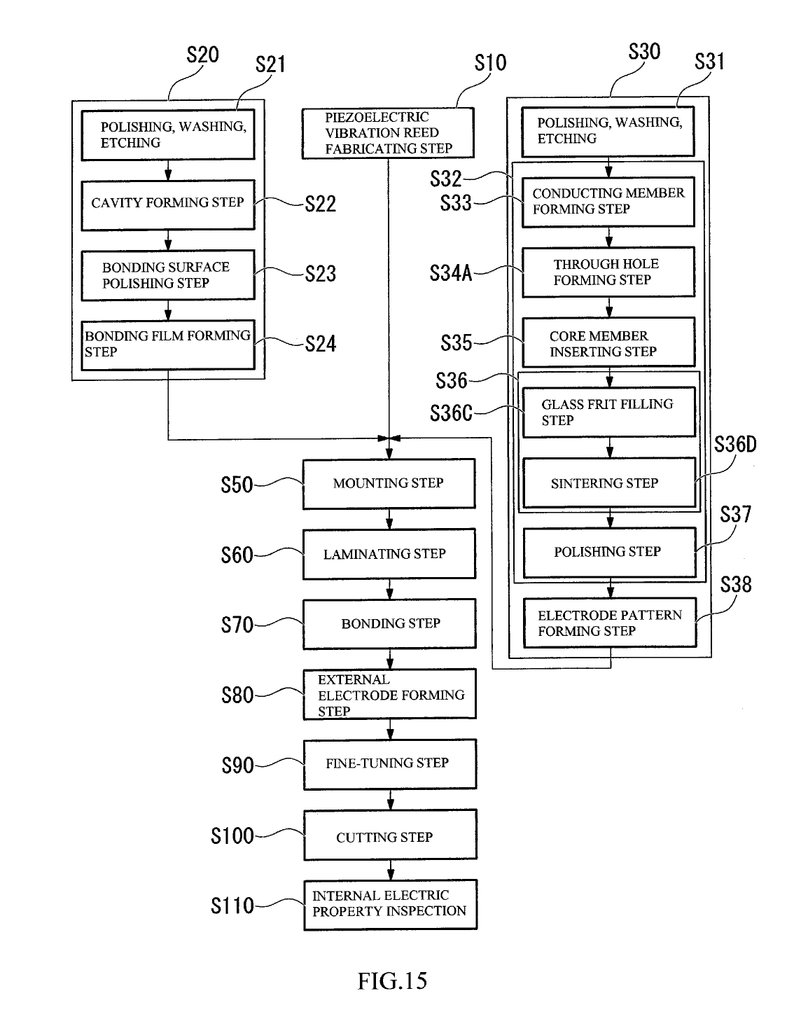

FIG. 14A is an explanatory drawing o showing stamping f according to a second modification of the first embodiment and, FIG. 14B is an explanatory drawing showing a raising of the core members according to the second first modification of the first embodiment.

In the conducting member forming step S33 in the first embodiment, the conducting member 5 is formed by forging the base material 55. In the first modification of the first embodiment, the conducting member 5 is formed by half-blanking the block member 56. However, the second modification of the first embodiment is different from the first embodiment and the first modification of the first embodiment in that the conducting member 5 is formed by stamping a flat-plate member 57 and then performing bending. Steps other than the conducting member forming step S33 are the same as those in the above-described embodiment, and hence repeated description is omitted.

The flat-plate member 57 is a member having a thickness on the order of 100 μm to 150 μm formed of a metallic material such as Ag, Al, Ni alloy, Kovar or the like.

As a procedure of the conducting member forming step S33 in the second modification, as shown in FIG. 14A, a substantially crank-shaped conducting panel member 5a is stamped out from the flat-plate member 57, for example, by pressing. The conducting panel member 5a includes a connecting portion forming portion 6a having a substantially rectangular shape in plan view and a core member forming portion 7a projecting horizontally from the connecting portion forming portion 6a. The stamping of the conducting panel member 5a is performed by using a blank die, not shown. In the second modification, a single piece of the conducting panel member 5a is stamped from the flat-plate member 57. However, it is also possible to stamp a plurality of the conducting panel members 5a simultaneously by so-called multi-cavity stamping. Also, by using a progressive die, the conducting panel members 5a may be stamped efficiently from the flat-plate member 57.

Subsequently, the core member forming portions 7a are bent so as to extend along the direction of the normal line of the connecting portion forming portion 6a. The bending of the core member forming portions 7a is performed by using a bend die, not shown. With the procedure described thus far, the conducting member 5 having the core members 7 and the connecting portion 6 is formed as shown in FIG. 14B.

### Advantages

According to the first modification and the second modification of the first embodiment, the conducting member 5 may be formed with high degree of accuracy at low cost by the half-blanking or the stamping. In particular, when the conducting members 5 are formed by stamping from the flat-plate member 57, a number of conducting members 5 may be formed at once, so that the conducting member 5 may be formed at lower cost.

### Second Modification, Another Through Electrode Forming Step

FIG. 15 is a flowchart showing a method of manufacturing the piezoelectric vibrator 1 according to a second embodiment.

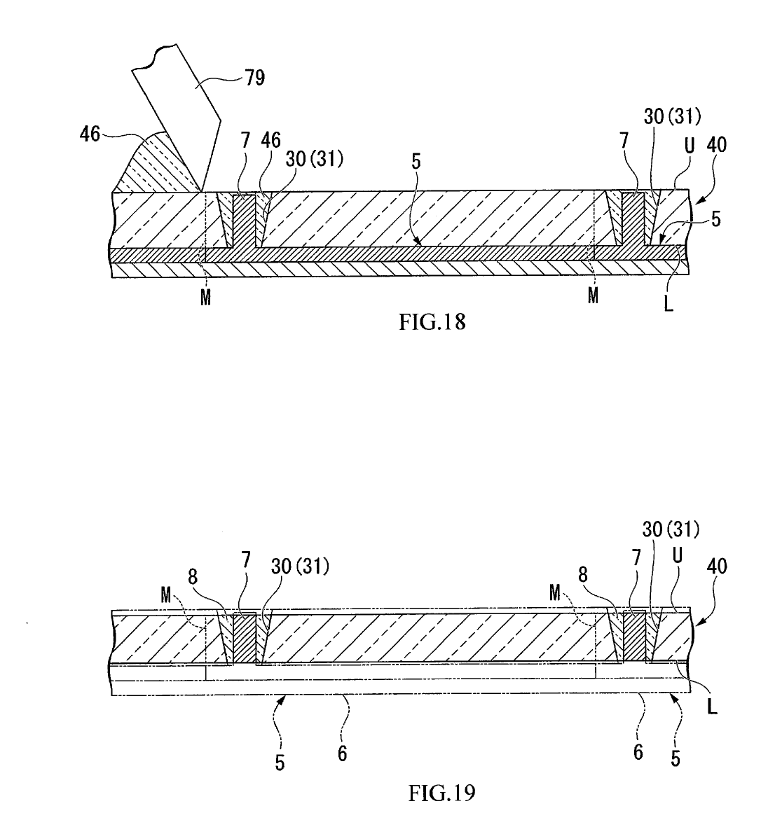

In the through hole forming step S32 in the first embodiment, the through electrodes 32, 33 are formed by forming the bottomed depressions 30a, 31a as depressions on the base substrate wafer 40, and sealing the depressions 30a, 31a by adhering the base substrate wafer 40 to the core members 7. However, the second embodiment is different from the first embodiment in that the through electrodes 32, 33 are formed by forming the through holes 30, 31 as the depressions, filling glass frit 46 (see FIG. 18) between the inner surfaces of the through holes 30, 31 and the outer surfaces of the core members 7 and sealing the through holes 30, 31. Since the configurations other than the through electrode forming step S32 are the same as those in the first embodiment, description will be omitted.

### Through Hole Forming Step S34A

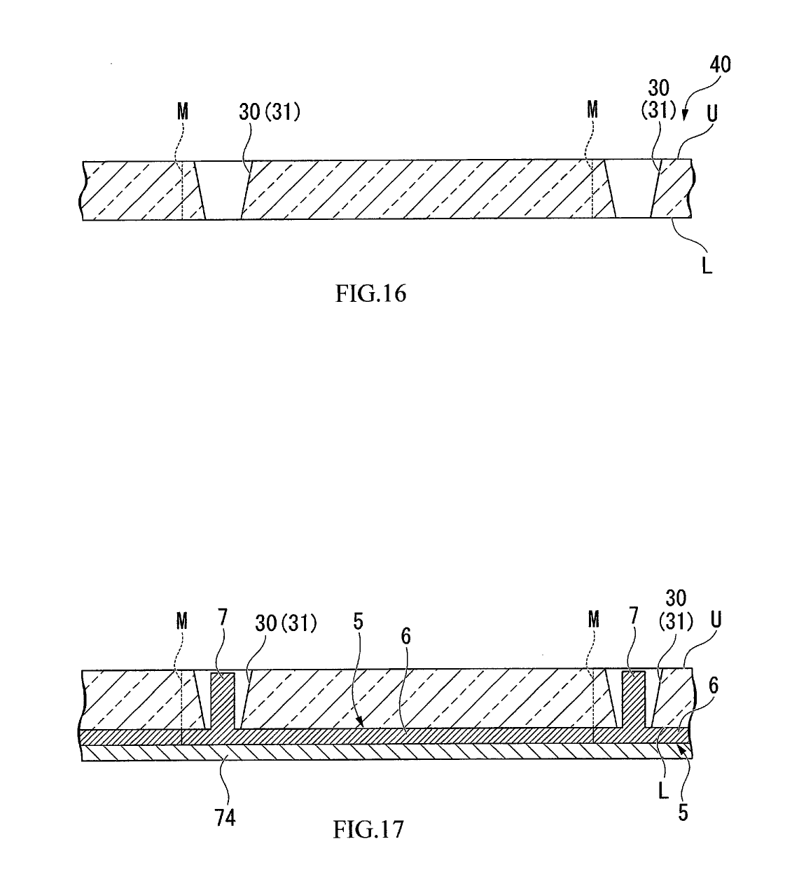

FIG. 16 is an explanatory drawing of a through hole forming step S34A.

In the through hole forming step S34A in the second embodiment, formation of the through holes 30, 31 penetrating through the first surface U and the second surface L of the base substrate wafer 40 is performed. In the same manner as the first embodiment, formation of the through holes 30, 31 are performed by heat pressing, sand-blasting, etching, or the like. It is preferable to form the through holes 30, 31 into a substantially truncated conical shape so as to be increased in inner diameter from the second surface L side to the first surface U side of the base substrate wafer 40. Accordingly, in the glass frit filling step S36C to be performed later, the through holes 30, 31 may be filled with the glass frit easily from the first surface U side having a larger opening.

### Core Member Inserting Step S35

FIG. 17 is an explanatory drawing of the core member inserting step S35.

In the core member inserting step S35 in the second embodiment, the core members 7 of the conducting member 5 are arranged in the through holes 30, 31. The length of the core members 7 is set to be slightly shorter (for example, on the order of 550 μm) than the thickness of the base substrate wafer 40 (for example, about 600 μm). Accordingly, in the glass frit filling step S36C described later, the through holes 30, 31 may be filled with the glass frit 46 without interference between the squeegee 79 and the core members 7.

The arrangement of the core members 7 is performed by setting the core members 7 in the arranging jig 74 so as to be directed upward and laminating the arranging jig 74 and the base substrate wafer 40 as in the first embodiment. However, it is preferable to insert the core members 7 into the through holes 30, 31 from the second surface L side as shown in FIG. 17. Accordingly, the glass frit may be filled from the first surface U side having a larger opening. The openings of the through holes 30, 31 on the second surface L side are closed by being covered with the connecting portion 6 and the arranging jig 74.

### Sealing Step S36

FIG. 18 is an explanatory drawing showing a grass frit filing step S36C in a sealing step S36.

The sealing step S36 in the second embodiment includes the glass frit filling step S36C for filing the glass frit 46 into the through holes 30, 31 and a sintering step S36D for sintering and hardening the glass frit 46.

### Glass Frit Filling Step S36C

First of all, the glass frit filling step S36C for filling the gaps between the inner surfaces of the through holes 30, 31 and the outer surfaces of the core members 7 with the glass frit 46 is performed.

The glass frit 46 is formed mainly of powdered glass and organic solvent.

As the detailed glass frit filling step S36C, the base substrate wafer 40 is transported and set into a chamber of a screen printer, not shown, and the interior of the chamber is vacuumed to produce a decompression atmosphere.

Subsequently, as shown in FIG. 18, the squeegee 79 is scanned along the first surface U and the glass frit 46 is applied from the first surface U side of the base substrate wafer 40. Since the outlines of the through holes 30, 31 on the first surface U side are larger than the outlines of the through holes 30, 31 on the second surface L side, the through holes 30, 31 may be filled with the glass frit 46 easily. Since the openings of the through holes 30, 31 on the second surface L side are closed by the connecting portion 6, the glass frit 46 is prevented from leaking therefrom.

### Sintering Step S36D

Subsequently, the sintering step S36D for sintering the glass frit 46 filled in the through holes 30, 31 is performed. For example, after having transported the base substrate wafer 40 into the sintering furnace, the base substrate wafer 40 is held under the atmosphere on the order of 610° C. for approximately 30 minutes. Accordingly, the glass frit 46 is solidified, and the through holes 30, 31, the glass frit 46, and the core members 7 are secured to each other, so that the gaps between the inner surfaces of the through holes 30, 31 and the outer surfaces of the core members 7 are sealed.

### Polishing Step S37

FIG. 19 is an explanatory drawing of the polishing step S37.

Subsequently, in the same manner as the first embodiment, the polishing step S37 for polishing the first surface U side and the second surface L side of the base substrate wafer 40 is performed. By polishing the first surface U side of the base substrate wafer 40, the core members 7 are exposed from the first surface U. Also, by polishing the second surface L side of the base substrate wafer 40, the connecting portions 6 of the conducting members 5 are removed, and the core members 7 are exposed from the second surface L. By the polishing step S37, the end portions of the core members 7 may be reliably exposed from the first surface U and the second surface L.

At the time point when the polishing step S37 is performed, the through electrode forming step S32 in the second embodiment is ended.

### Effects of Second Embodiment

According to the second embodiment, since the respective core members 7 to be arranged in one single piece of the piezoelectric vibrator 1 are connected by the connecting portion 6, even when the through holes 30, 31 is filled with the glass frit 46, the positional displacement between the respective core members 7 arranged in the single piece of the piezoelectric vibrator 1 does not occur. Therefore, manufacturing defects are prevented and hence the continuity of the through electrodes 32, 33 is ensured, the through electrodes 32, 33 with high reliability may be formed. In addition, since the glass frit 46 filled in the gaps between the inner surfaces of the through holes 30, 31 and the outer surfaces of the core members 7 is sintered and hardened, the through electrodes 32, 33 with high hermeticity may be formed.

### Third Embodiment, a Conducting Member Having a Number of Core Members and an Example Thereof.

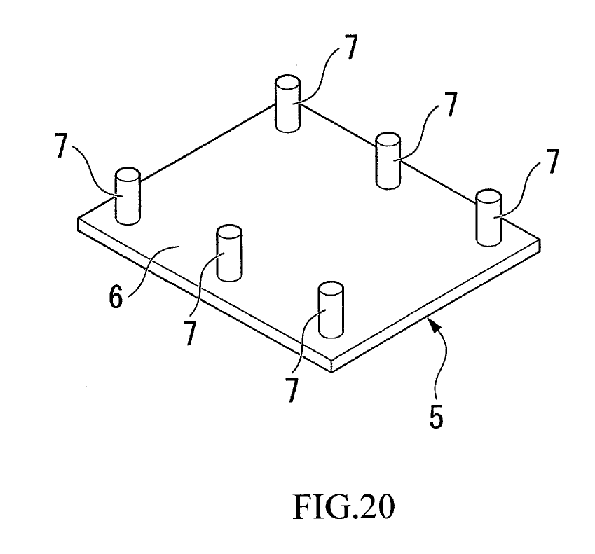

FIG. 20 is a perspective view of a conducting member 5 according to a third embodiment.

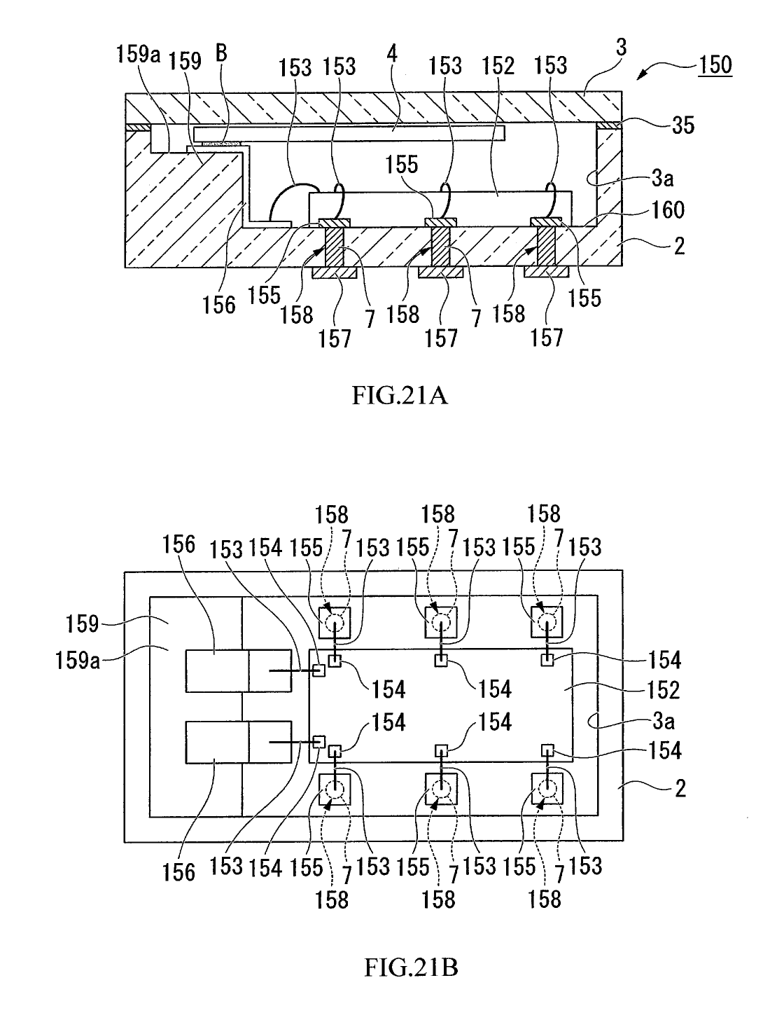

FIG. 21A is an explanatory cross-sectional side view of an oscillator 150 using the conducting member 5 in FIG. 20, and FIG. 21B is an explanatory plan view of the oscillator 150 using the conducting member in FIGS. 21A and 21B. In FIG. 21B, illustration of the lid substrate 3 and the piezoelectric vibration reed 4 is omitted for the sake of easy understanding of the drawings.

In the first embodiment and the second embodiment, the piezoelectric vibrator 1 is formed using the conducting member 5 having a pair of the core members 7. However, the third embodiment is different from the first embodiment and the second embodiment in that the oscillator 150 having the piezoelectric vibration reed 4 and an IC chip 152 (which corresponds to the “integrated circuit” in Claims) encapsulating in a package is formed using the conducting member 5 having six core members 7. Repeated description of the same contents as the first embodiment and the second embodiment in detail is omitted.

As shown in FIG. 20, the conducting member 5 in the third embodiment includes six of the core members 7 and the connecting portion 6 for connecting the respective core members 7. The core members 7 are formed upright on the connecting portion 6 at positions corresponding to a plurality of internal electrodes 155 formed on the base substrate 2 shown in FIGS. 21A and 21B.

The connecting portion 6 is a flat-panel member having, for example, a substantially rectangular shape in plan view. The outline of the connecting portion 6 is formed to be slightly smaller than the outline of the oscillator and to be larger than the outline of the IC chip 152. Accordingly, the core members 7 may be arranged outside the IC chip 152. Since the material and the method of manufacturing of the conducting member 5 in the third embodiment are the same as those in the first embodiment and the second embodiment, repeated description is omitted.

As shown in FIGS. 21A and 21B, the oscillator 150 is formed by encapsulating the piezoelectric vibration reed 4 and the IC chip 152 in the cavity 3a formed between the base substrate 2 and the lid substrate 3.

The base substrate 2 in the third embodiment is formed with the cavity 3a. The cavity 3a is formed with a stepped portion 159 having one level difference from the opening side to the bottom surface side of the cavity 3a.

The opening side of the cavity 3a of the stepped portion 159 corresponds to a vibration reed mounting portion 159a, and the bottom portion of the cavity 3a corresponds to an IC chip mounting portion 160. The drawing electrode 156 is routed between the vibration reed mounting portion 159a and the IC chip mounting portion 160. The piezoelectric vibration reed 4 is mounted on the drawing electrodes 156 formed on the vibration reed mounting portion 159a via the bumps B.

The IC chip 152 is mounted on the IC chip mounting portion 160. The IC chip 152 controls the piezoelectric vibration reed 4 by producing an output of frequency signals, for example. The IC chip 152 is formed with a plurality of electrode pads 154, which are wire-bonded to the internal electrodes 155 and the drawing electrodes 156 formed in the periphery of the IC chip 152 via wires 153.

The internal electrodes 155 and external electrodes 157 are connected by the through electrodes 158 penetrating through the base substrate 2 in the thickness direction. The through electrodes 158 are formed of the core members 7 of the conducting member 5 in the same manner as the first embodiment and the second embodiment. The through electrodes 158 are formed by inserting the core members 7 into depressions (or through holes), sealing the gaps between the inner surfaces of the depressions and the outer surfaces of the core members 7 and removing the connecting portion 6 of the conducting member 5 by polishing or the like in the same manner as in the first embodiment and the second embodiment.

### Effects of Third Embodiment

In this manner, even when the IC chip 152 having a plurality of input and output signals is encapsulated in the package to form a number of through electrodes 158, by using the conducting member 5 having a number of the core members 7, the same effects as in the first embodiment and the second embodiments are achieved. In other words, since the core members 7 may be arranged easily in all the depressions (or through holes) included in a single piece of the package of the base substrate 2, the through electrodes 158 may be formed easily. Also, since the respective core members are connected by the connecting portion, the positional displacement between the core members does not occur. Therefore, manufacturing defects are prevented and hence the continuity of the through electrodes 158 is secured, so that the through electrodes with high reliability may be formed.

According to the oscillator in the third embodiment, since the piezoelectric vibration reed 4 and the IC chip are encapsulated in the interior of the package having the through electrodes 158 which may be formed easily and have high degree of reliability, the oscillator 150 with high degree of reliability may be provided at low cost.

### Oscillator

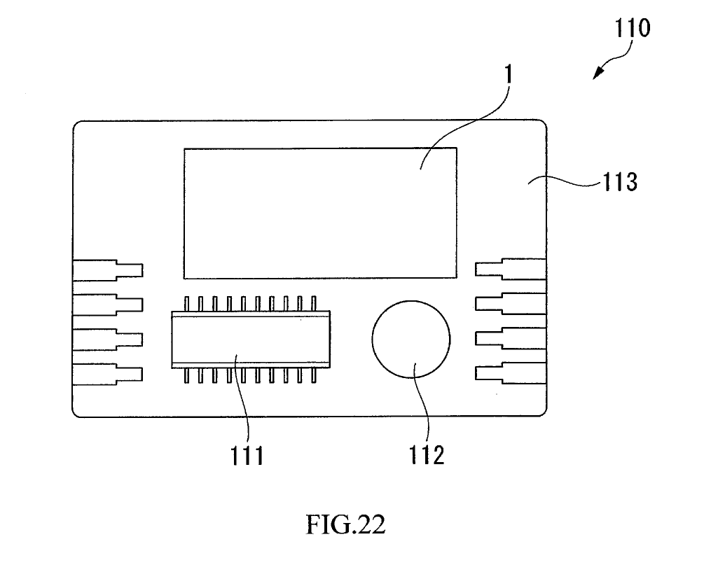

Subsequently, an embodiment of the oscillator according to the present invention will be described with reference to FIG. 22.

The oscillator 150 according to the third embodiment described above is an oscillator obtained by connecting the piezoelectric vibration reed and the integrated circuit in the interior of the package 9. However, the oscillator 110 described below, being different from the oscillator 150 in the third embodiment, is obtained by using the piezoelectric vibrator in the first embodiment and the second embodiment as an oscillation element which is electrically connected to the external integrated circuit.

The oscillator 110 in the third embodiment includes the piezoelectric vibrator 1 as an oscillation element electrically connected to an integrated circuit 111 as shown in FIG. 22. The oscillator 110 includes a substrate 113 on which an electronic device component 112 such as a capacitor is mounted. The integrated circuit 111 for the oscillator is mounted on the substrate 113, and a piezoelectric vibration reed of the piezoelectric vibrator 1 is mounted in the vicinity of the integrated circuit 111. The electronic device component 112, the integrated circuit 111, and the piezoelectric vibrator 1 are electrically connected to each other with a wring pattern, not shown. The respective components are molded by resin, not shown.

In the oscillator 110 configured as described above, when a voltage is applied to the piezoelectric vibrator 1, the piezoelectric vibration reed in the piezoelectric vibrator 1 vibrates. This vibration is converted into an electric signal by the piezoelectric characteristic of the piezoelectric oscillation reed and is entered into the integrated circuit 111 as the electric signal. The entered electric signal is subjected to various sorts of processing by the integrated circuit 111, and is supplied as an output of a frequency signal. Accordingly, the piezoelectric vibrator 1 functions as the oscillation element.

Also, by selectively setting the configuration of the integrated circuit 111, for example, a RTC (real time clock) module or the like according to the requirement, not only a function as a single function oscillator for a time piece, but also a function to control the date of operation or the time instant of the corresponding apparatus or an external apparatus or to provide the time instant or a calendar or the like of the same may be added.

According to the oscillator 110 in the third embodiment, since the piezoelectric vibrator 1 manufactured by the manufacturing method which ensures a reliable continuity of the through electrodes while maintaining the hermeticity in the cavity is provided, the oscillator 110 having good performance and being superior in reliability may be provided.

### Electronic Apparatus

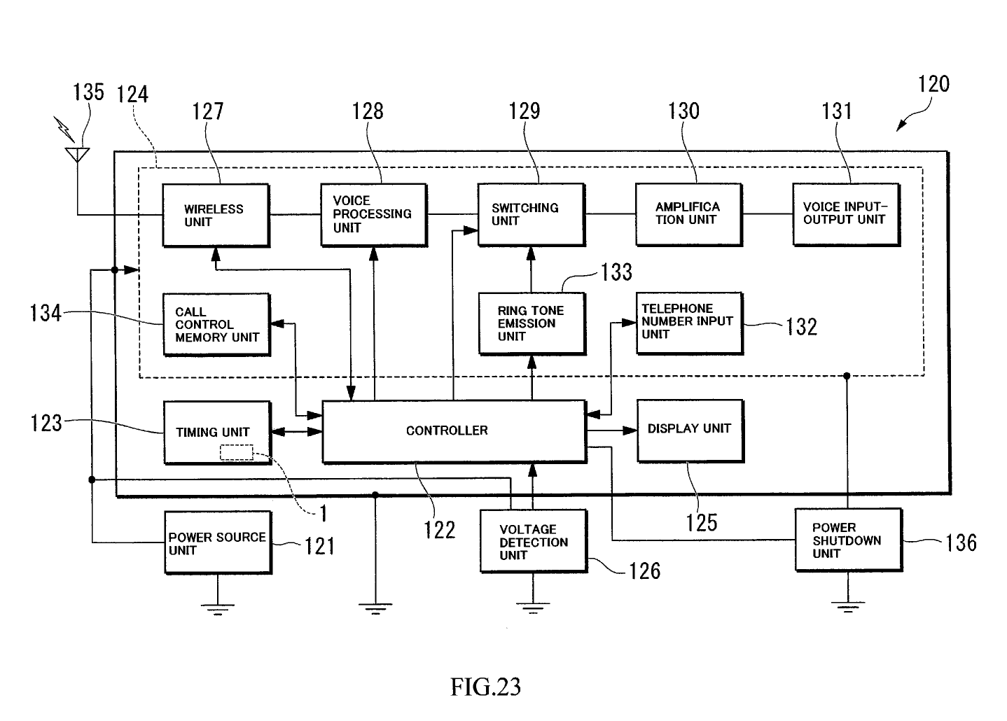

Subsequently, an embodiment of an electronic apparatus according to the invention will be described with reference to FIG. 23. As the electronic apparatus, a portable digital assistant device 120 having the piezoelectric vibrator 1 described above will be exemplified for description. First of all, the portable digital assistant device 120 of this embodiment is represented, for example, by a mobile phone set, and development and improvement of a wrist watch in the related art. The appearance is similar to the wrist watch, and a liquid crystal display is arranged on a portion corresponding to a dial, so that the current time instance or the like may be displayed on a screen thereof. When using as a communication instrument, it is removed from the wrist, and communication which is the same as the mobile phone set in the related art is achieved with a speaker and a microphone built in an inner portion of a band. However, reduction in size and weight is achieved significantly in comparison with the mobile phone set in the related art.

Subsequently, a configuration of the portable digital assistant device 120 according to the second embodiment will be described. The portable digital assistant device 120 includes the piezoelectric vibrator 1 and a power source unit 121 for supplying electric power as shown in FIG. 23. The power source unit 121 is composed, for example, of a lithium secondary battery. Connected in parallel to the power source unit 121 are a control unit 122 configured to perform various controls, a clocking unit 123 configured to perform clocking of time instance or the like, a communication unit 124 configured to perform communication with the outside, a display unit 125 configured to display various items of information, and a voltage detection unit 126 configured to detect the voltages of the respective functioning portions. The power source unit 121 is configured to supply electric power to the respective functioning portions.

The control unit 122 controls respective functioning portions to perform action control of an entire system such as sending and receiving of the voice data, or measurement or display of the current time instance. Also, the control unit 122 includes a ROM in which a program is written in advance, a CPU configured to read and execute the program written in the ROM, and a RAM used as a work area of the CPU.

The clocking unit 123 includes an integrated circuit having an oscillating circuit, a register circuit, a counter circuit, and an interface circuit integrated therein, and the piezoelectric vibrator 1. When a voltage is applied to the piezoelectric vibrator 1, the piezoelectric vibration reed vibrates, and this vibration is converted into an electric signal by a piezoelectric characteristic of crystal and is entered into the oscillating circuit as the electric signal. The output of the oscillating circuit is binarized, and is counted by the register circuit and the counter circuit. Then, sending and receiving of the signal with respect to the control unit 122 is performed via the interface circuit, and the current time instance, the current date, the calendar information, or the like are displayed on the display unit 125.

The communication unit 124 has the same function as the mobile phone set in the related art, and includes a wireless unit 127, a voice processing unit 128, a switching unit 129, an amplifying unit 130, a voice input and output unit 131, a telephone number input unit 132, an incoming call ring tone generating unit 133, and a calling control memory unit 134.

The wireless unit 127 sends and receives various data such as the voice data with respect to a base station via an antenna 135. The voice processing unit 128 codes and decodes the voice signal received as an input from the wireless unit 127 or the amplifying unit 130. The amplifying unit 130 amplifies the signal received as an input from the voice processing unit 128 or the voice input and output unit 131 to a predetermined level. The voice input and output unit 131 includes a speaker and a microphone, and reinforces an incoming call ring tone or a receiving voice, or collects the voice.

Also, the incoming call ring tone generating unit 133 generates the incoming call ring tone according to the call from the base station. The switching unit 129 switches the amplifying unit 130 connected to the voice processing unit 128 to the incoming call ring tone generating unit 133 only at the time of the incoming call, so that the incoming call ring tone generated by the incoming call ring tone generating unit 133 is supplied as an output to the voice input and output unit 131 via the amplifying unit 130.

The calling control memory unit 134 stores the program relating to communication dialing and incoming ring tone control. Also, the telephone number input unit 132 includes, for example, numeral keys from 0 to 9 and other keys, and a telephone number of a call target is entered by pressing these numeral keys and the like.

The voltage detecting unit 126 detects a voltage drop when the voltage applied to the respective functional portions such as the control unit 122 or the like by the power source unit 121 falls below the predetermined value, and notifies it to the control unit 122. The predetermined voltage at this time is a value preset as a minimum voltage for stably operating the communication unit 124 and, for example, is on the order of 3V. The control unit 122, upon reception of the notification about the voltage drop from the voltage detecting unit 126, restricts the operations of the wireless unit 127, the voice processing unit 128, the switching unit 129, and the incoming call ring tone generating unit 133. In particular, the stop of the operation of the wireless unit 127 which consumes a large amount of power is essential. Furthermore, the fact that the communication unit 124 is disabled due to the short of the remaining amount of battery is displayed on the display unit 125.

In other words, the operation of the communication unit 124 may be restricted by the voltage detecting unit 126 and the control unit 122, and this may be displayed on the display unit 125. This display may be a text message, but may be a cross mark on a telephone icon displayed on an upper portion of the display surface of the display unit 125 as a further visceral display.

By providing a power source blocking unit 136 which is capable of selectively disconnect the power source of a portion relating to the function of the communication unit 124, the function of the communication unit 124 may be stopped further reliably.

According to the portable digital assistant device 120 in the third embodiment, since the piezoelectric vibrator 1 manufactured by the manufacturing method which ensures a reliable continuity of the through electrodes while maintaining the hermeticity in the cavity is provided, the portable digital assistant device 120 having good performance and being superior in reliability may be provided.

### Radio Clock

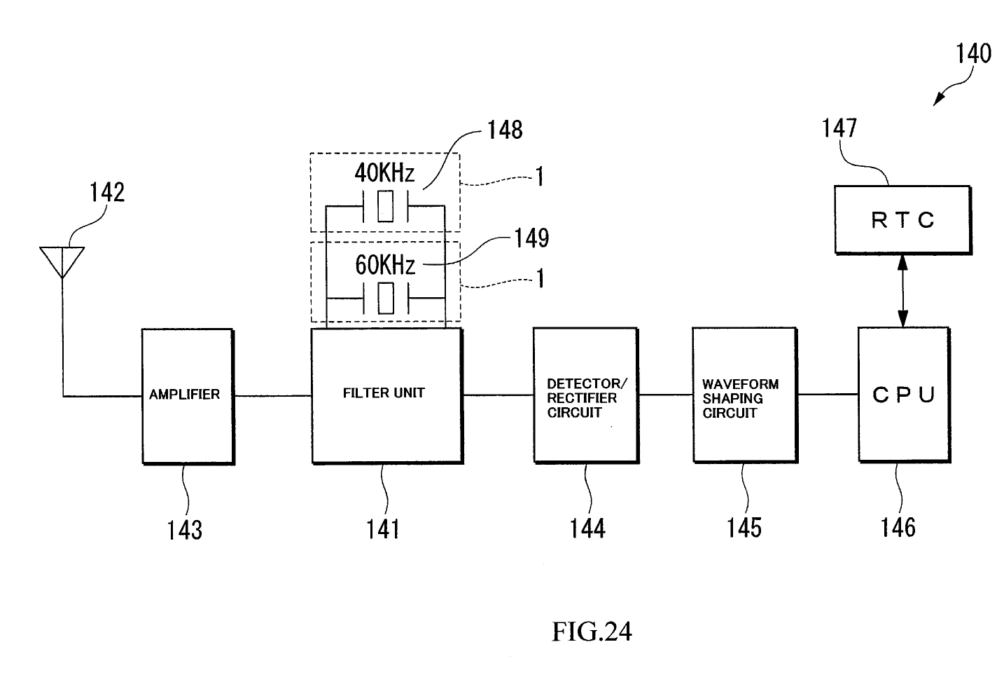

Subsequently, an embodiment of a radio clock according to the invention will be described with reference to FIG. 24.

A radio clock 140 includes the piezoelectric vibrator 1 electrically connected to a filtering unit 141 as shown in FIG. 24, and is a timepiece configured to receive a standard radio wave including timepiece data, correct the same to an accurate time instance and display the same.

In Japan, transmitter points (transmitter stations) which transmit the standard radio wave in Fukushima-ken (40 kHz) and Saga-ken (60 kHz), and these stations transmit the standard radio waves respectively. Long radio waves such as 40 kHz or 60 kHz have both a feature to propagate on the ground surface and a feature to propagate while being reflected between the inosphere and the ground surface, so that it has a large propagation range, and hence Japan is entirely covered by the above-described two transmitter stations.

A functional configuration of the radio clock 140 will be described in detail below.

The antenna 142 receives a long standard radio wave of 40 kHz or 60 kHz. The long reference radio wave is generated by AM-modulating the hour instance data referred to as a time code into a carrier wave of 40 kHz or 60 kHz. The received long reference radio wave is amplified by an amplifier 143 and filtered and synchronized by the filtering unit 141 having a plurality of the piezoelectric vibrators 1. The piezoelectric vibrators 1 in this embodiment each include quartz vibrator units 148 and 149 having a resonance frequency of 40 kHz and 60 kHz which are the same as the above-described carrier frequency.

Furthermore, the filtered signal having the predetermined frequency is detected and demodulated by a detecting and rectifying circuit 144.

Subsequently, the time code is acquired via a waveform shaping circuit 145, and is counted by a CPU 146. In the CPU 146, data such as the current year, the cumulated day, the day of the week, the time instance is read. The read data is reflected on the RTC 148, and the accurate time instance data is displayed. Since the carrier wave is of 40 kHz or 60 kHz, the quartz vibrator units 148 and 149 are preferably vibrators having the tuning fork type structure described above.

The description given above is about the example in Japan and the frequency of the low frequency standard wave is different in other countries. For example, in Germany, a standard wave of 77.5 KHz is used. Therefore, when integrating the radio clock 140 for overseas use into portable equipment, the piezoelectric vibrator 1 having a different frequency from Japan is necessary.

According to the radio clock 140 in the third embodiment, since the piezoelectric vibrator 1 manufactured by the manufacturing method which ensures a reliable continuity of the through electrodes while maintaining the hermeticity in the cavity is provided, the radio clock 140 having good performance and being superior in reliability may be provided.

The invention is not limited to the above-described embodiments.

In the first embodiment and the second embodiment, the method of manufacturing packages 9 of the invention has been described with an example of the piezoelectric vibrator 1 in which a tuning fork type piezoelectric vibration reed 4 is employed. However, for example, it is also possible to employ the method of manufacturing packages 9 in the invention described above for the piezoelectric vibrator using an AT-cut type piezoelectric vibration reed (thickness shear vibrating reed).

In the first embodiment and the second embodiment, the piezoelectric vibrator 1 is manufactured by encapsulating the piezoelectric vibration reed 4 in the interior of the package 9 while using the method of manufacturing packages 9 according to the invention. However, it is also possible to manufacture devices other than the piezoelectric vibrator by encapsulating electronic components other than the piezoelectric vibration reed 4 in the interior of the package 9.

In the through electrode forming step S32 in the first embodiment, the through electrodes 32, 33 are formed by forming the depressions 30a, 31a on the base substrate wafer 40, and adhering the base substrate wafer 40 to the core members 7. However, for example, it is also possible to form the through hole on the base substrate wafer 40 and adhering the base substrate wafer 40 to the core members 7 to form the through electrodes 32, 33.

The conducting member 5 in the first embodiment and the second embodiment includes a pair of the core members 7, and the conducting member 5 in the third embodiment has six of the core members 7. However, the number of the core members 7 of the conducting member 5 is not limited thereto, and a larger number of core members 7 may be provided.

In the first embodiment and the respective modifications of the first embodiment, the conducting member 5 is formed by forging, half-blanking, or pressing. However, the method of manufacturing the conducting member 5 is not limited to the forging, the half-blanking, and the pressing.

In the first embodiment, the base substrate wafer 40 is heated and melted to seal the gaps between the inner surfaces of the depressions 30a, 31a and the outer surfaces of the core members 7. In the second embodiment, the glass frit 46 is filled between the inner surfaces of the through holes 30, 31 and the outer surfaces of the core members 7 to seal the gaps between the inner surfaces of the through holes 30, 31 and the outer surfaces of the core members 7. However, the method of sealing the gaps between the inner surfaces of the depressions 30a, 31a (through holes 30, 31) and the outer surfaces of the core members 7 is not limited to the method of sealing according to the first embodiment and the second embodiment.

What is claimed is:

1. A method for producing piezoelectric vibrators, comprising:
(a) defining a plurality of first substrates on a first wafer and a plurality of second substrates on a second wafer;
(b) forming holes in a respective at least some of the first substrates on the first wafer;
(c) arranging multiple conductive columns standing at locations coincident with locations of at least some of the holes;
(d) substantially simultaneously inserting at least some of the conductive columns into corresponding holes; and
(e) securing at least some of the inserted conductive columns within corresponding holes.

2. The method according to claim 1, further comprising removing at least one main surface of the first wafer to expose both ends of the conductive columns from the first wafer.

3. The method according to claim 1 further comprising:
(f) layering the first and second wafers such that at least some of the first substrates which have the conductive columns secured therein substantially coincide respectively with at least some of the corresponding second substrates;
(g) bonding at least some of the coinciding first and second substrate pairs; and
(h) cutting off a respective at least some of the bonded first and second substrate pairs from the layered first and second wafers.

4. The method according to claim 1, wherein forming holes comprises forming holes having a bottom at a depth greater than a length of the conductive column.

5. The method according to claim 1, wherein arranging multiple conductive columns comprises defining conductive columns in groups each comprising a holder that maintains a geometrical relationship of conductive columns standing from the holder.

6. The method according to claim 4, wherein arranging multiple conductive columns comprises arranging the holders each placed in contact with a neighboring holder.

7. The method according to claim 4, wherein defining conductive columns in groups comprises defining conductive columns in pairs in each of which the holder maintains a geometrical relationship of a pair of conductive columns standing from the holder.

8. The method according to claim 4, further comprising integrally forming the holder and the conductive columns standing from the holder.

9. The method according to claim 8, wherein integrally forming the holder and the conductive columns comprises forming the holder integral with the conductive columns by forging.

10. The method according to claim 8, wherein integrally forming the holder and the conductive columns comprises forming the holder integral with the conductive columns by half-banking.

11. The method according to claim 8, wherein integrally forming the holder and the conductive columns comprises forming the holder integral with the conductive columns by stamping.

12. The method according to claim 1, wherein securing at least some of the inserted conductive columns comprises pressing the first wafer under heat to close the holes in which the conductive columns are inserted.

13. The method according to claim 1, wherein securing at least some of the inserted conductive columns comprises using paste to fill at least some of the holes in which the conductive columns are inserted and heating the first wafer to harden the paste in the holes.
